(19) United States
(12) Patent Application Publication
(10) Pub. No.: US 2024/0388055 A1
(43) Pub. Date: Nov. 21, 2024

(54) SEMICONDUCTOR LIGHT EMITTING DEVICE AND METHOD FOR MANUFACTURING SEMICONDUCTOR LIGHT EMITTING DEVICE

(71) Applicant: ROHM CO., LTD., Kyoto-shi (JP)

(72) Inventor: Akito SHINODA, Kyoto-shi (JP)

(21) Appl. No.: 18/665,140

(22) Filed: May 15, 2024

(30) Foreign Application Priority Data
May 17, 2023 (JP) 2023-081640

(51) Int. Cl. H01S 5/02208; H01S 5/02345

(52) U.S. Cl. CPC H01S 5/02208; H01S 5/02345

(57) ABSTRACT

A semiconductor light emitting device includes a substrate, an edge-emitting light emitting element placed on the substrate, a cap accommodating the edge-emitting light emitting element, an adhesion pattern, a first adhesive, a connecting portion, and a second adhesive. The adhesion pattern is disposed on the substrate so as to surround the edge-emitting light emitting element in plan view. The first adhesive bonds the cap to the pattern surface of the adhesion pattern. The connecting portion laterally extends through at least the adhesion pattern in plan view to connect the inside and the outside of the cap to each other. The connecting portion is filled with the second adhesive.

### CROSS-REFERENCE TO RELATED APPLICATIONS

This application is based upon and claims the benefit of priority from prior Japanese Patent Application No. 2023-081640, filed on May 17, 2023, the entire contents of which are incorporated herein by reference.

### BACKGROUND

### 1. Field

The present disclosure relates to a semiconductor light emitting device and a method for manufacturing a semiconductor light emitting device.

### 2. Description of Related Art

A semiconductor light emitting device is known that includes a substrate, a semiconductor light emitting element placed on the substrate, and a cap placed on the substrate to accommodate the semiconductor light emitting element (for example, see Japanese Laid-Open Patent Publication No. 2021-174820). In this semiconductor light emitting device, the cap is bonded to the substrate using an adhesive, for example.

### BRIEF DESCRIPTION OF THE DRAWINGS

FIG. 1 is a perspective view of a semiconductor light emitting device according to one embodiment.

FIG. 2 is a schematic plan view showing the internal structure of the semiconductor light emitting device shown in FIG. 1.

FIG. 3 is a schematic cross-sectional view of the semiconductor light emitting device taken along line F3-F3 in FIG. 2.

FIG. 4 is an enlarged schematic plan view of a part of the adhesion pattern shown in FIG. 2.

FIG. 5 is an enlarged schematic side view of a part of the side structure of the semiconductor light emitting device shown in FIG. 1.

FIG. 6 is an enlarged schematic cross-sectional view of a second adhesive and its surrounding area in FIG. 3.

FIG. 7 is a plan view showing a manufacturing step of a semiconductor light emitting device according to one embodiment.

FIG. 8 is a schematic plan view showing a manufacturing step after the step shown in FIG. 7.

FIG. 9 is a schematic end view showing a manufacturing step after the step of FIG. 8 and the end structure taken along line F9-F9 in FIG. 8.

FIG. 10 is a schematic end view showing a manufacturing step after the step shown in FIG. 9.

FIG. 11 is a schematic end view showing a manufacturing step after the step shown in FIG. 10.

FIG. 12 is a schematic end view showing a manufacturing step after the step shown in FIG. 11.

FIG. 13 is a schematic plan view showing a manufacturing step after the step shown in FIG. 12.

FIG. 14 is a schematic plan view showing the internal structure of a semiconductor light emitting device according to a modification.

FIG. 15 is a schematic plan view showing the internal structure of a semiconductor light emitting device according to a modification.

FIG. 16 is a schematic plan view showing the internal structure of a semiconductor light emitting device according to a modification.

FIG. 17 is a schematic plan view showing the internal structure of a semiconductor light emitting device according to a modification.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

Some embodiments of a semiconductor light emitting device and a method for manufacturing a semiconductor light emitting device of the present disclosure will be described with reference to the accompanying drawings. In the drawings, elements may not be drawn to scale for simplicity and clarity of illustration. In a cross-sectional view, hatching may be omitted to facilitate understanding. The accompanying drawings are merely illustrative of embodiments of the disclosure and should not be considered as limiting the disclosure.

The detailed description below includes devices, systems, and methods that are exemplary embodiments of the present disclosure. This detailed description is merely intended for explanatory purposes, and does not intend to limit the embodiments of the present disclosure, nor the application or usage of such embodiments.

In the following descriptions, the expressions that “the width (dimension) of component A is equal to the width (dimension) of component B,” “the length (dimension) of component A is equal to the length (dimension) of component B,” and “the thickness (dimension) of component A is equal to the thickness (dimension) of component B” refer to that the difference between the width (length, thickness) dimension of component A and the width (length, thickness) dimension of component B is within 10% of the width (length, thickness) dimension of component A.

### Overall Configuration of Semiconductor Light Emitting Device

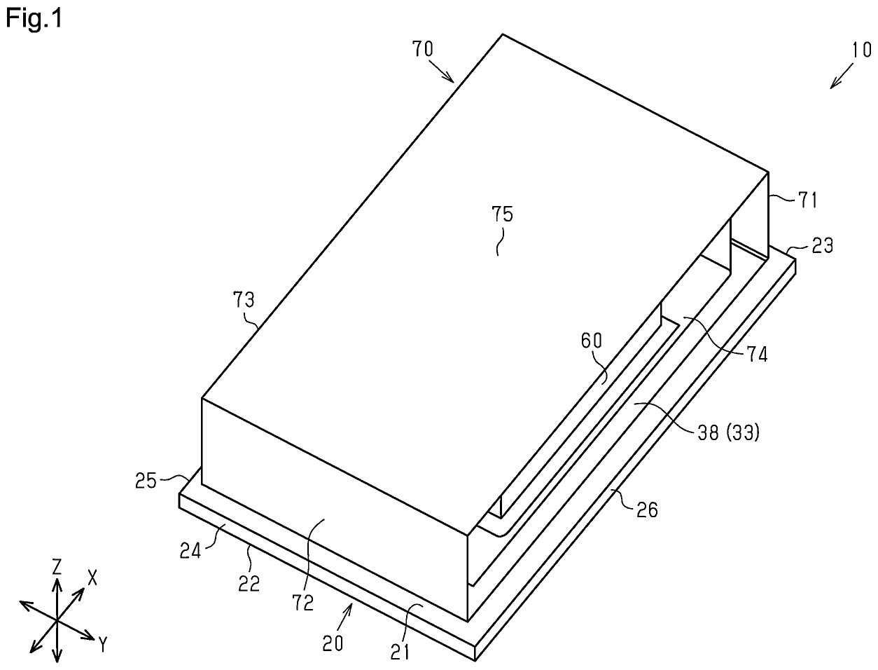

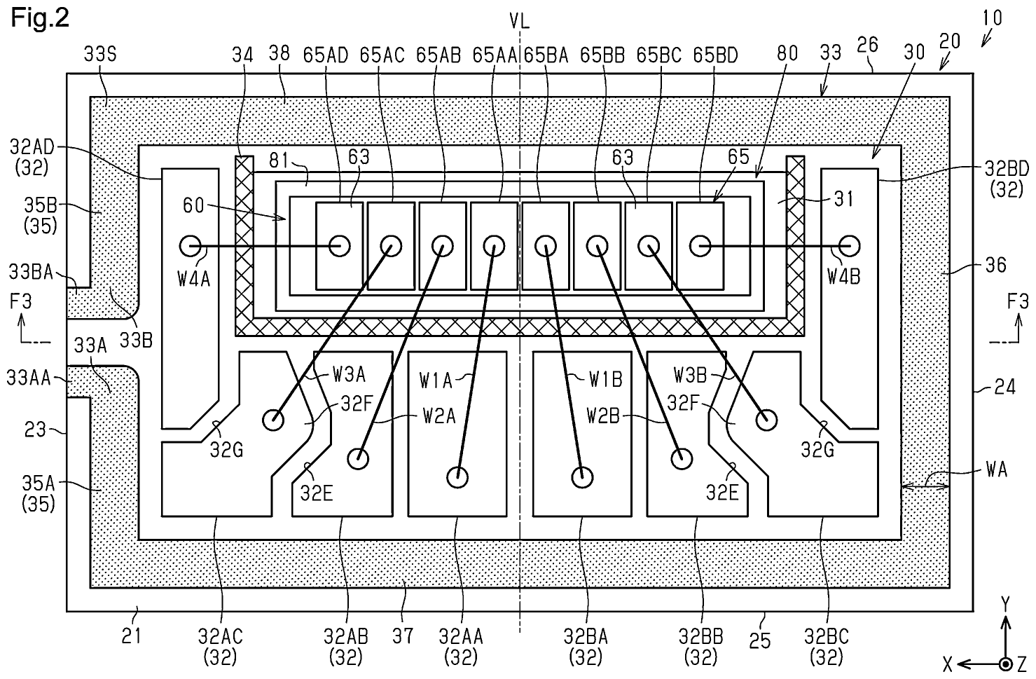

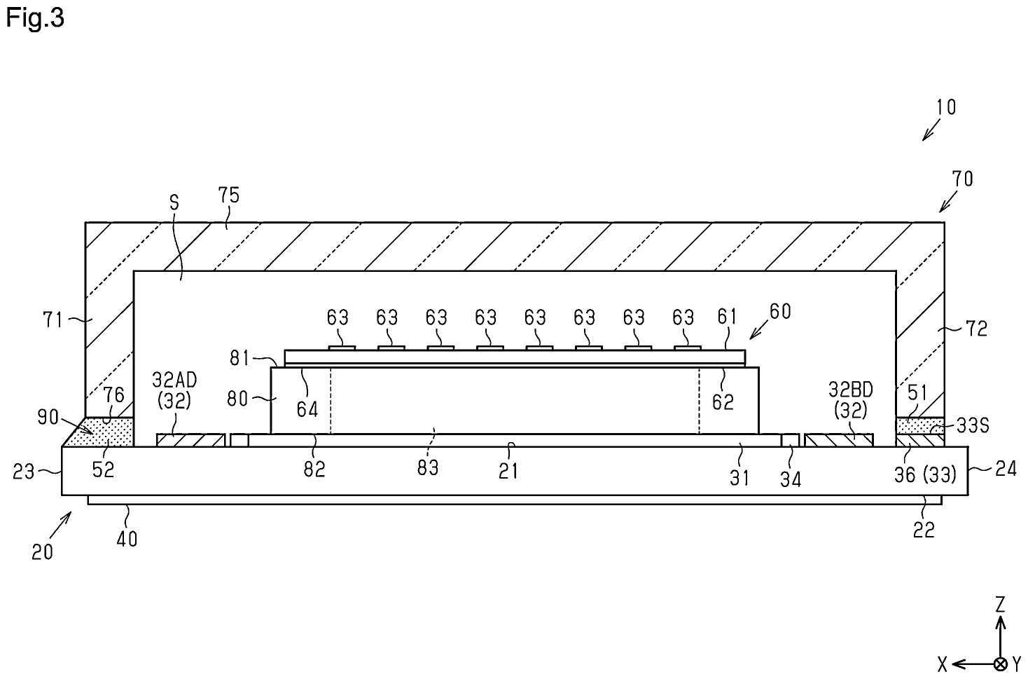

Referring to FIGS. 1 to 3, the overall configuration of a semiconductor light emitting device 10 according to one embodiment is now described. FIG. 1 shows the perspective structure of a semiconductor light emitting device 10. FIG. 2 schematically shows the planar structure inside the semiconductor light emitting device 10. FIG. 3 shows a cross-sectional structure of the semiconductor light emitting device 10 taken along line F3-F3 in FIG. 2. To facilitate the understanding of the drawing, wires W, which will be described below, are omitted in FIG. 3.

As shown in FIG. 1, the semiconductor light emitting device 10 includes a rectangular flat substrate 20, an edge-emitting light emitting element 60 placed on the substrate 20 (see FIG. 2), and a cap 70, which is placed on the substrate 20 and accommodates the edge-emitting light emitting element 60. The thickness direction of the substrate 20 is referred to as a Z-direction. The Z-direction may also be considered as the thickness direction of the semiconductor light emitting device 10. Of the directions perpendicular to the Z-direction, two perpendicular directions are referred to as the X-direction and the Y-direction. Furthermore, as used herein, plan view refers to viewing the semiconductor light emitting device 10 from the thickness direction (Z-direction) of the substrate 20. In the example of FIG. 1, the substrate 20 is formed in a rectangular shape having a longitudinal direction in the X-direction and a transverse direction in the Y-direction in plan view.

The substrate 20 includes a substrate surface 21 and a substrate back surface 22, which face away from each other in the Z-directions, and first to fourth substrate side surfaces 23 to 26, which intersect the substrate surface 21 and the substrate back surface 22. In the first embodiment, the substrate surface 21 and the substrate back surface 22 are both formed as planes perpendicular to the Z-direction. In one example, the first to fourth substrate side surfaces 23 to 26 are planes perpendicular to the substrate surface 21 and the substrate back surface 22. The first and second substrate side surfaces 23 and 24 form opposite end surfaces of the substrate 20 in the X-direction, and the third and fourth substrate side surfaces 25 and 26 form opposite end surfaces of the substrate 20 in the Y-direction.

In one example, the substrate 20 is made of glass epoxy resin. The substrate 20 may be made of a material containing ceramic. Examples of the material containing ceramic include aluminum nitride (AlN) and alumina (Al₂O₃). When the substrate 20 is made of a material containing ceramic, the heat dissipation performance of the substrate 20 is improved. This limits an excessive increase in the temperature of the edge-emitting light emitting element 60.

As shown in FIG. 2, the edge-emitting light emitting element 60 may be a laser diode that emits light in a predetermined wavelength band, and functions as a light source of the semiconductor light emitting device 10. The edge-emitting light emitting element 60 is an edge-emitting laser element. There is no particular limitation on the edge-emitting light emitting element 60 as an edge-emitting laser element. The present embodiment uses a Fabry-Perot laser diode. In one example, the edge-emitting light emitting element 60 is configured to emit light toward the fourth substrate side surface 26 in plan view. The edge-emitting light emitting element 60 corresponds to “a semiconductor light emitting element.” The edge-emitting light emitting element 60 also corresponds to “a semiconductor laser element.”

The semiconductor light emitting device 10 includes multiple (nine in the example of FIG. 2) surface electrodes 30 formed on the substrate surface 21 of the substrate 20. The surface electrodes 30 are spaced apart from each other. The surface electrodes 30 are formed of copper foil and gold (Au) plating formed on the copper foil, for example. The material of the surface electrodes 30 is not limited to copper (Cu) and Au. The material may include at least one of aluminum (Al), nickel (Ni), palladium (Pd), or silver (Ag).

The surface electrodes 30 include an element surface electrode 31 and multiple (eight in the example of FIG. 2) wire connection electrodes 32. The element surface electrode 31 and the wire connection electrodes 32 are surface electrodes electrically connected to the edge-emitting light emitting element 60.

The element surface electrode 31 is located closer to the fourth substrate side surface 26 than the center of the substrate surface 21 in the Y-direction. The element surface electrode 31 has a rectangular shape having a longitudinal direction in the X-direction and a transverse direction in the Y-direction. In one example, the dimension of the element surface electrode 31 in the X-direction is greater than twice the dimension in the Y-direction and less than four times the dimension in the Y-direction. In one example, the dimension of the element surface electrode 31 in the X-direction is greater than ½ of the dimension of the substrate surface 21 in the X-direction.

A resist pattern 34 is formed around the element surface electrode 31. The resist pattern 34 is formed in a U-shape that surrounds the element surface electrode 31 at opposite sides in the X-direction, and the side corresponding to the third substrate side surface 25 in the Y-direction in plan view. The resist pattern 34 may be made of an insulating material. The insulating material may be epoxy resin, for example.

The wire connection electrodes 32 are arranged so as to surround the element surface electrode 31. More specifically, the wire connection electrodes 32 are arranged at opposite sides of the element surface electrode 31 in the X-direction, and the side of the element surface electrode 31 closer to the third substrate side surface 25. The wire connection electrodes 32 are not located at the side of the element surface electrode 31 closer to the fourth substrate side surface 26. It may be considered that the wire connection electrodes 32 are arranged so as to surround the edge-emitting light emitting element 60. Details of the wire connection electrodes 32 will be described below.

The semiconductor light emitting device 10 includes a submount substrate 80 mounted on the element surface electrode 31. In one example, the submount substrate 80 is die-bonded to the element surface electrode 31. The submount substrate 80 is a substrate that supports the edge-emitting light emitting element 60 and is made of a material containing ceramic, for example. Examples of the material containing ceramic include AlN and Al₂O₃. When the submount substrate 80 is made of a material containing ceramic, the heat dissipation performance of the submount substrate 80 is improved. This facilitates the transmission of heat from the edge-emitting light emitting element 60 to the substrate 20 through the submount substrate 80. As a result, the temperature of the edge-emitting light emitting element 60 is unlikely to be excessively high.

The material of the submount substrate 80 may be modified. The submount substrate 80 may be made of a metal material with high conductivity and heat dissipation. For example, the metal material may be Ag, Cu, or the like. In one example, the submount substrate 80 is a rectangular flat plate made of Cu. In another example, the submount substrate 80 may be made of a material containing silicon (Si).

As shown in FIGS. 2 and 3, the submount substrate 80 has the shape of a rectangular flat plate having a thickness direction in the Z-direction. In one example, the submount substrate 80 is rectangular and has a longitudinal direction in the X-direction and a transverse direction in the Y-direction in plan view. In one example, the submount substrate 80 has a smaller size than the element surface electrode 31 in plan view.

As shown in FIG. 3, the submount substrate 80 has a greater thickness than the substrate 20. The thickness of the submount substrate 80 may be modified, and may be less than or equal to the thickness of the substrate 20, for example.

The submount substrate 80 has a front surface 81 and a back surface 82, which face away from each other in the Z-direction. In the example of FIG. 3, the front and back surfaces 81 and 82 are both formed as planes perpendicular to the Z-direction. The front surface 81 faces the same side as the substrate surface 21, and the back surface 82 faces the same side as the substrate back surface 22. The edge-emitting light emitting element 60 is mounted on the front surface 81 of the submount substrate 80. In one example, the edge-emitting light emitting element 60 is die-bonded to the front surface 81 of the submount substrate 80.

The submount substrate 80 includes a through-substrate interconnection 83, which extends through the submount substrate 80 in the thickness direction. The through-substrate interconnection 83 electrically connects the edge-emitting light emitting element 60 to the element surface electrode 31. The through-substrate interconnection 83 may be made of a material containing Cu. The material of the through-substrate interconnection 83 is not limited to Cu, and may include at least one of titanium (Ti), tungsten (W), or Al. The number of through-substrate interconnections 83 may be modified. In one example, multiple through-substrate interconnections 83 are provided.

When the submount substrate 80 is made of a conductive material such as Cu, the through-substrate interconnection 83 can be omitted. That is, the conductive submount substrate 80 may electrically connect the edge-emitting light emitting element 60 to the element surface electrode 31.

As shown in FIGS. 2 and 3, the edge-emitting light emitting element 60 mounted on the submount substrate 80 has the shape of a rectangular flat plate having a thickness direction in the Z-direction. The edge-emitting light emitting element 60 is rectangular and has a longitudinal direction in the X-direction and a transverse direction in the Y-direction in plan view. In one example, the edge-emitting light emitting element 60 has a smaller size than the submount substrate 80 in plan view.

The thickness of the edge-emitting light emitting element 60 is less than the thickness of the submount substrate 80. The thickness of the edge-emitting light emitting element 60 is less than the thickness of the substrate 20. Nevertheless, the thickness of the edge-emitting light emitting element 60 may be modified. For example, the thickness may be greater than or equal to the thickness of the substrate 20 or greater than or equal to the thickness of the submount substrate 80.

The edge-emitting light emitting element 60 includes an element surface 61 and an element back surface 62, which face away from each other in the Z-direction. In the example of FIG. 3, the element surface 61 and the element back surface 62 are both formed as planes perpendicular to the Z-direction. The edge-emitting light emitting element 60 includes multiple (eight in the example of FIG. 3) element electrodes 63, which are formed on the element surface 61, and a back electrode 64 forming the element back surface 62. The edge-emitting light emitting element 60 includes a light emitting portion 65 (see FIG. 2) for each element electrode 63. In plan view, the element electrodes 63 are spaced apart in the X-direction. As such, the multiple (eight in the example of FIG. 2) light emitting portions 65 are arranged in the X-direction. Each light emitting portion 65 is configured to emit laser light toward the fourth substrate side surface 26 in plan view.

Each element electrode 63 is rectangular and has a longitudinal direction in the Y-direction and a transverse direction in the X-direction in plan view. In the example of FIG. 3, the element electrodes 63 form the anode electrodes of the respective light emitting portions 65. For example, the back electrode 64 may be formed over the entire element back surface 62 of the edge-emitting light emitting element 60. In the example of FIG. 3, the back electrode 64 forms a common cathode electrode for the multiple light emitting portions 65. The element electrodes 63 and the back electrode 64 may be made of Au, for example. The material of the element electrodes 63 and the back electrode 64 is not limited to Au and may include at least one of Al, Ni, Pd, Ag, or Cu.

The edge-emitting light emitting element 60 is mounted on the submount substrate 80 using a conductive bonding material (not shown). As such, the conductive bonding material electrically connects the back electrode 64 to the submount substrate 80 (through-substrate interconnection 83). The through-substrate interconnection 83 electrically connects the back electrode 64 to the element surface electrode 31. Examples of the conductive bonding material include a solder paste and a silver paste.

As shown in FIG. 2, the semiconductor light emitting device 10 includes wires W1A to W4A and W1B to W4B, which electrically connect the respective light emitting portions 65 to the corresponding wire connection electrodes 32. The wires W1A to W4A and W1B to W4B may be bonding wires, for example. The wires W1A to W4A and W1B to W4B are made of a material containing Au, for example. The wires W1A to W4A and W1B to W4B may be made of a material containing at least one of Cu, Ag, or Al, instead of Au.

As shown in FIG. 3, the semiconductor light emitting device 10 includes multiple (nine in one example) back electrodes 40 formed on the substrate back surface 22 of the substrate 20. The back electrodes 40 are spaced apart from each other. The number of the back electrodes 40 is set according to the number of the surface electrodes 30 (see FIG. 2). The back electrodes 40 may be formed by copper foil and Au plating formed on the copper foil, for example. The material of the back electrodes 40 is not limited to Au and may include at least one of Al, Ni, Pd, or Ag.

Although not shown, the back electrodes 40 include an element back electrode and multiple (eight in one example) wire back electrodes. The element back electrode is electrically connected to the element surface electrode 31. The wire back electrodes are electrically connected to the respective wire connection electrodes 32 (see FIG. 2) formed on the substrate surface 21. Although not shown, the back electrodes 40 are electrically connected to the respective surface electrodes 30 by separate through-substrate interconnections. Each through-substrate interconnection extends through the substrate 20 in the thickness direction (Z-direction).

As shown in FIG. 2, the semiconductor light emitting device 10 includes an adhesion pattern 33 formed on the substrate surface 21. The adhesion pattern 33 includes a pattern surface 33S facing the same side as the substrate surface 21. In one example, the adhesion pattern 33 has a frame shape having a predetermined width and extending in a length direction perpendicular to the width. The adhesion pattern 33 has the shape of a frame surrounding the surface electrodes 30 in plan view. In one example, the adhesion pattern 33 has a rectangular frame shape. In the example of FIG. 2, the adhesion pattern 33 has a rectangular frame shape having a longitudinal direction in the X-direction and a transverse direction in the Y-direction. In one example, the outer periphery of the adhesion pattern 33 has a smaller size than the outer periphery of the substrate 20. In one example, the adhesion pattern 33 has a uniform width dimension WA over the entire perimeter. The width dimension WA of the adhesion pattern 33 is a dimension in a direction perpendicular to the direction in which the adhesion pattern 33 extends (length direction) in plan view. In one example, the thickness dimension of the adhesion pattern 33 may be 50 μm or more and 100 μm or less. In one example, the width dimension WA of the adhesion pattern 33 may be 50 μm or more and 500 μm or less.

The adhesion pattern 33 is formed by a metal layer, for example. In one example, the adhesion pattern 33 is made of the same material as the surface electrodes 30. The adhesion pattern 33 may be made of a material different from that of the surface electrodes 30. In one example, the adhesion pattern 33 may be formed by an insulating layer. The adhesion pattern 33 may be made of the same material as the resist pattern 34, for example.

The adhesion pattern 33, which is a metal layer or an insulating layer, slightly protrudes from the substrate surface 21 in the Z-direction. In one example, the thickness of the adhesion pattern 33 is equal to the thickness of the surface electrodes 30, for example. The thickness of the adhesion pattern 33 may be modified, and may be thicker or thinner than the thickness of the surface electrodes 30.

The pattern surface 33S of the adhesion pattern 33 may be formed by a flat surface perpendicular to the Z-direction. A first adhesive 51 (see FIG. 3) is applied to the pattern surface 33S of the adhesion pattern 33. The first adhesive 51 may be formed over the entire perimeter of the adhesion pattern 33 in plan view, for example. Since the adhesion pattern 33 limits spreading of the first adhesive 51, the first adhesive 51 is unlikely to extend beyond the adhesion pattern 33.

As shown in FIG. 3, a cap 70 is fixed on the adhesion pattern 33 by the first adhesive 51. As such, the cap 70 may be considered to be disposed on the substrate 20. The cap 70 has the shape of a box opening in the Z-direction toward the substrate 20. In one example, the cap 70 is made of a glass material. The cap 70 may be made of a resin material instead of a glass material. Examples of the resin material include acrylic resin and epoxy resin. Also, the cap 70 may be made of metal or ceramic. Examples of the metal include Al, iron (Fe), and Cu. Examples of the ceramic include AlN and Al₂O₃.

As shown in FIG. 1, the cap 70 includes first to fourth side walls 71 to 74, which have a rectangular frame shape in plan view, and an upper wall 75, which closes one of the openings in the Z-directions formed by the first to fourth side walls 71 to 74. The first to fourth side walls 71 to 74 correspond to “a side wall.” In one example, the first to fourth side walls 71 to 74 and the upper wall 75 are integrally formed. The first and second side walls 71 and 72 form side walls at opposite ends of the cap 70 in the X-direction, and the third and fourth side walls 73 and 74 form side walls at opposite ends of the cap 70 in the Y-direction. The first side wall 71 forms one of opposite side walls in the X-direction of the cap 70 that is closer to the first substrate side surface 23 of the substrate 20. The second side wall 72 forms the side wall that is closer to the second substrate side surface 24 of the substrate 20. The third side wall 73 forms one of opposite side walls in the Y-direction of the cap 70 that is closer to the third substrate side surface 25 of the substrate 20. The fourth side wall 74 forms the side wall that is closer to the fourth substrate side surface 26 of the substrate 20. The first to fourth side walls 71 to 74 are opposed to the adhesion pattern 33 in the Z-direction. The first to fourth side walls 71 to 74 have the same shape as the adhesion pattern 33 in plan view. Accordingly, the first to fourth side walls 71 to 74 have a rectangular shape having a longitudinal direction in the X-direction and a transverse direction in the Y-direction in plan view. The first and second side walls 71 and 72, which extend in the Y-direction in plan view, form the sections of the first to fourth side walls 71 to 74 that extend in the transverse direction. The third and fourth side walls 73 and 74, which extend in the x direction in plan view, form the sections of the first to fourth side walls 71 to 74 that extend in the longitudinal direction.

As shown in FIG. 3, the cap 70 includes an opening end surface 76. The opening end surface 76 is formed by the distal end surfaces of the first to fourth side walls 71 to 74. The opening end surface 76 may be formed by a flat surface extending in a direction perpendicular to the Z-direction, for example.

In one example, when the cap 70 is made of a glass material or a resin material, the first to third side walls 71 to 73 and the upper wall 75 are translucent, and the fourth side wall 74 is transparent. The laser light emitted by the edge-emitting light emitting element 60 passes through the fourth side wall 74 and is emitted to the outside of the semiconductor light emitting device 10. That is, the fourth side wall 74 includes a light transmission surface, which transmits the laser light from the edge-emitting light emitting element 60. The fourth side wall 74 is opposed to a part of the adhesion pattern 33 in the Z-direction. As such, it may be considered that the cap 70 includes a light transmission surface at a position corresponding to the adhesion pattern 33 in plan view. Also, the fourth side wall 74 forms a section of the first to fourth side walls 71 to 74 that extends in the longitudinal direction. As such, it may be considered that the light transmission surface is formed in a section of the first to fourth side walls 71 to 74 that extends in the longitudinal direction.

In one example, the cap 70 is made of metal or ceramic, and the fourth side wall 74 includes an opening and a window member, which closes the opening and transmits the laser light from the edge-emitting light emitting element 60. The fourth side wall 74 thus includes a light transmission surface.

### Configuration of Wire Connection Electrode

Referring to FIG. 2, the detailed configuration of the wire connection electrodes 32 is now described.

As shown in FIG. 2, the wire connection electrodes 32 are symmetrical with respect to an imaginary center line VL that is at the center of the substrate 20 in the X-direction and extends in the Y-direction in plan view. Hereinafter, of the wire connection electrodes 32, the four wire connection electrodes 32 closer to the first substrate side surface 23 than the imaginary center line VL are referred to as wire connection electrodes 32AA, 32AB, 32AC, and 32AD, and the four wire connection electrodes 32 closer to the second substrate side surface 24 than the imaginary center line VL are referred to as wire connection electrodes 32BA, 32BB, 32BC, and 32BD. The wire connection electrodes 32AA to 32AD are arranged in the order of the wire connection electrodes 32AA, 32AB, 32AC, and 32AD in a direction away from the imaginary center line VL, that is, from the imaginary center line VL toward the first substrate side surface 23. The wire connection electrodes 32BA to 32BD are arranged in the order of the wire connection electrodes 32BA, 32BB, 32BC, and 32BD in a direction away from the imaginary center line VL, that is, from the imaginary center line VL toward the second substrate side surface 24.

The wire connection electrodes 32AA to 32AC and 32BA to 32BC are aligned with the element surface electrodes 31 as viewed from the Y-direction. The wire connection electrodes 32AD and 32BD are arranged separately on opposite sides of the element surface electrode 31 in the X-direction.

Since the wire connection electrodes 32BA to 32BD and the wire connection electrodes 32AA to 32AD are symmetrical with respect to the imaginary center line VL, the following description focuses on the wire connection electrodes 32AA to 32AD, and detailed descriptions of the wire connection electrodes 32BA to 32BD are omitted.

The wire connection electrodes 32AA to 32AC are arranged uniformly in the Y-direction and spaced apart from each other in the X-direction. The wire connection electrodes 32AA to 32AC have the same dimension in the Y-direction.

The wire connection electrode 32AA is rectangular and has a longitudinal direction in the Y-direction and a transverse direction in the X-direction in plan view.

One of end portions in the X-direction of the wire connection electrode 32AB that is closer to the wire connection electrode 32AC includes a recess 32E, which is recessed toward the wire connection electrode 32AA. The recess 32E includes a base surface and two inclined surfaces, which are inclined so as to be farther from the wire connection electrode 32AC in the Y-directions from the base surface. In one example, the base surface of the recess 32E extends in the Y-direction in plan view. One of opposite end surfaces in the X-direction of the wire connection electrode 32AB that is closer to the wire connection electrode 32AA extends in the Y-direction in plan view. The shape of the base surface of the recess 32E in plan view may be modified. In one example, the base surface of the recess 32E has a concave shape in plan view.

The wire connection electrode 32AC includes a protrusion 32F, which protrudes into the recess 32E of the wire connection electrode 32AB, and a cutout section 32G, which is cut out so as to accommodate the wire connection electrode 32AD.

The protrusion 32F includes a distal end surface, which is opposed to the base surface of the recess 32E in the X-direction, and two inclined surfaces parallel to the two inclined surfaces of the recess 32E in plan view. The inclined surfaces of the protrusion 32F are opposed to the inclined surfaces of the recess 32E in the X-direction.

The cutout section 32G is formed in a section of the wire connection electrode 32AC that is in the side farther from the wire connection electrode 32AB in the X-direction and is closer to the element surface electrode 31 in the Y-direction. The cutout section 32G includes a section that is aligned with the protrusion 32F as viewed in the X-direction. The protrusion 32F thus prevents the dimension of the wire connection electrode 32AC in the X-direction from being excessively reduced by the presence of the cutout section 32G.

The wire connection electrode 32AD extends in the Y-direction. The dimension of the wire connection electrode 32AD in the Y-direction is greater than the dimension of the element surface electrode 31 in the Y-direction. In the Y-direction, a section of the wire connection electrode 32AD that protrudes toward the third substrate side surface 25 beyond the element surface electrode 31 extends into the cutout section 32G of the wire connection electrode 32AC. The distal end of the section of the wire connection electrode 32AD extending in the cutout section 32G is tapered corresponding to the shape of the cutout section 32G.

The arrangement relationship between the wire connection electrodes 32AA to 32AD and the light emitting portions 65 is now described.

The light emitting portions 65 include light emitting portions 65AA to 65AD corresponding to the wire connection electrodes 32AA to 32AD, and light emitting portions 65BA to 65BD corresponding to the wire connection electrodes 32BA to 32BD. The light emitting portions 65AA to 65AD are arranged at the same position in the Y-direction and spaced apart from each other in the X-direction. The light emitting portions 65AA to 65AD are arranged in the order of the light emitting portions 65AA, 65AB, 65AC, and 65AD in a direction away from the imaginary center line VL, that is, from the imaginary center line VL toward the first substrate side surface 23. The light emitting portions 65BA to 65BD are arranged in the order of the light emitting portions 65BA, 65BB, 65BC, and 65BD in a direction away from the imaginary center line VL, that is, from the imaginary center line VL toward the second substrate side surface 24.

The wire connection electrode 32AA is aligned with the light emitting portions 65AA and 65AB in the Y-direction in plan view.

The wire connection electrode 32AB is arranged closer to the first substrate side surface 23 than the light emitting portion 65AB in plan view. The wire connection electrode 32AB is aligned with the light emitting portions 65AC and 65AD in the Y-direction in plan view.

The wire connection electrode 32AC is closer to the first substrate side surface 23 than the light emitting portion 65AC in plan view. The wire connection electrode 32AC is also closer to the first substrate side surface 23 than the light emitting portion 65AD in plan view.

The wire connection electrode 32AD is closer to the first substrate side surface 23 than the light emitting portion 65AD in plan view. The wire connection electrode 32AD is opposed to the light emitting portion 65AD in the X-direction in plan view.

The connection configuration is now described in which the light emitting portions 65 of the edge-emitting light emitting element 60 and the wire connection electrodes 32AA to 32AD and 32BA to 32BD are connected by the wires W1A to W4A and W1B to W4B.

The wire W1A connecting the light emitting portion 65AA and the wire connection electrode 32AA is connected to a section of the wire connection electrode 32AA that is on the opposite side of the center in the Y-direction from the light emitting portion 65AA.

The wire W2A connecting the light emitting portion 65AB and the wire connection electrode 32AB is connected to a section of the wire connection electrode 32AB that is on the opposite side of the base surface of the recess 32E from the light emitting portion 65AB in the Y-direction.

The wire W3A connecting the light emitting portion 65AC and the wire connection electrode 32AC is connected to a section of the wire connection electrode 32AC that is substantially at the same position in the Y-direction as the distal end surface of the protrusion 32F.

The wire W4A connecting the light emitting portion 65AD and the wire connection electrode 32AD extends in the X-direction in plan view, for example. In this manner, the wires W1A to W4A are connected to the wire connection electrodes 32AA to 32AD such that the variations in the lengths of the wires W1A to W4A in plan view are reduced.

The wire W1B connecting the light emitting portion 65BA and the wire connection electrode 32BA, the wire W2B connecting the light emitting portion 65BB and the wire connection electrode 32BB, the wire W3B connecting the light emitting portion 65BC and the wire connection electrode 32BC, and the wire W4B connecting the light emitting portion 65BD and the wire connection electrode 32BD are connected to the wire connection electrodes 32BA to 32BD in the same manner as the wires W1A to W4A.

### Configuration of Adhesion Pattern

Referring to FIGS. 2 to 5, the detailed structure of the adhesion pattern 33 is now described.

The adhesion pattern 33, which has a rectangular frame shape in plan view, includes a first pattern 35 and a second pattern 36, which are spaced apart from each other in the X-direction, and a third pattern 37 and a fourth pattern 38, which are spaced apart from each other in the Y-direction. The first and second patterns 35 and 36 are both strip-shaped and extend in the Y-direction. The third and fourth patterns 37 and 38 are both strip-shaped and extend in the X-direction. The third pattern 37 and the fourth pattern 38 are connected to opposite ends of the first pattern 35 and the second pattern 36 in the Y-direction, thereby forming the adhesion pattern 33 having a rectangular frame shape.

The first pattern 35 is formed at a position adjacent to the first substrate side surface 23 in the X-direction in plan view. The second pattern 36 is formed at a position adjacent to the second substrate side surface 24 in plan view. The first pattern 35 is formed at a position adjacent to the wire connection electrodes 32AC and 32AD in plan view. The second pattern 36 is formed at a position adjacent to the wire connection electrodes 32BC and 32BD in plan view.

The third pattern 37 is formed at a position adjacent to the third substrate side surface 25 in the Y-direction in plan view. The fourth pattern 38 is formed at a position adjacent to the fourth substrate side surface 26 in the Y-direction in plan view. The third pattern 37 is formed at a position adjacent to the wire connection electrodes 32AA to 32AC and 32BA to 32BC in the Y-direction in plan view. The fourth pattern 38 is located at a position adjacent to the element surface electrode 31 and the wire connection electrodes 32AD and 32BD in the Y-direction. As such, it may be considered that the edge-emitting light emitting element 60 is arranged at a position adjacent to the fourth pattern 38 in the Y-direction in plan view.

In the example shown in FIG. 2, the length dimension (dimension in the X-direction) of the third and fourth patterns 37 and 38 is greater than the length dimension (dimension in the Y-direction) of the first and second patterns 35 and 36. That is, the first and second patterns 35 and 36 form the sections of the adhesion pattern 33 that extend in the transverse direction, and the third and fourth patterns 37 and 38 form the sections of the adhesion pattern 33 that extend in the longitudinal direction.

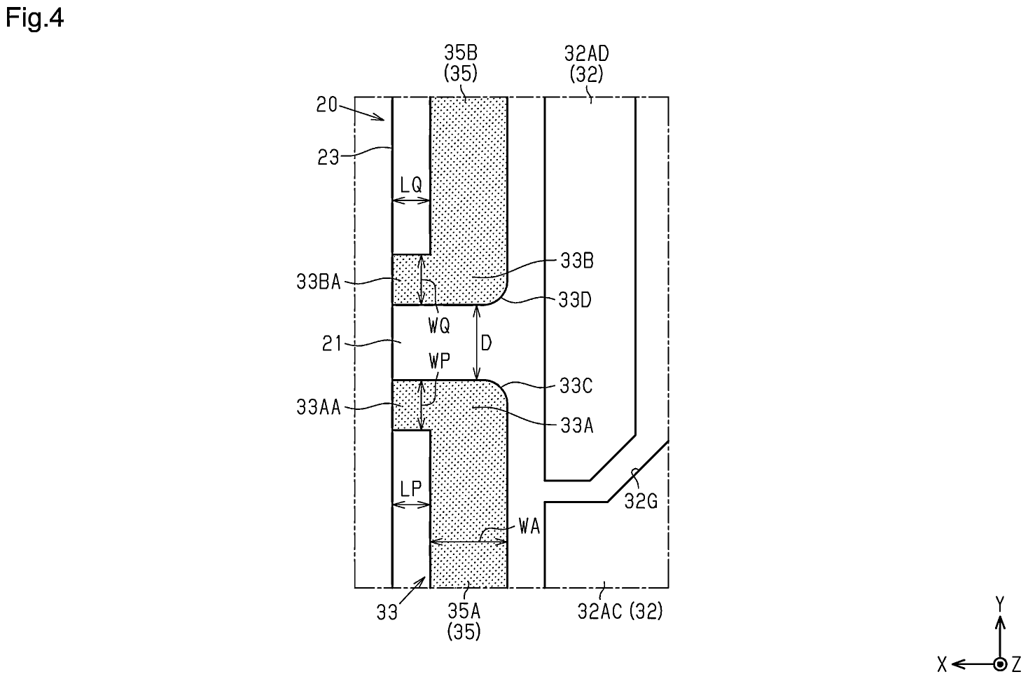

FIG. 4 is an enlarged view of a part of the first pattern 35 and its surrounding area.

As shown in FIG. 4, the adhesion pattern 33 includes a section that extends through the adhesion pattern 33 in the width direction (the X-direction in the example of FIG. 4) and thus splits the adhesion pattern 33 in the length direction (the Y-direction in the example of FIG. 4). More specifically, the first pattern 35 includes a first split pattern 35A and a second split pattern 35B, which are physically separated in the Y-direction.

The first split pattern 35A is a section of the first pattern 35 that is connected to the third pattern 37 (see FIG. 2). The second split pattern 35B is a section of the first pattern 35 that is connected to the fourth pattern 38 (see FIG. 2). The first and second split patterns 35A and 35B extend in the Y-direction.

In one example, the first and second split patterns 35A and 35B are equal in length dimension (dimension in the Y-direction). That is, the first and second split patterns 35A and 35B are separated at the center of the first pattern 35 in the Y-direction.

The distal end portions of the first and second split patterns 35A and 35B are opposed to and spaced apart from each other in the Y-direction. As such, it may be considered that the distal end portions of the first and second split patterns 35A and 35B form perimeter end portions of the adhesion pattern 33. That is, the adhesion pattern 33 includes a first perimeter end portion 33A and a second perimeter end portion 33B, which are opposed to each other. The distal end portion of the first split pattern 35A forms the first perimeter end portion 33A. The distal end portion of the second split pattern 35B forms the second perimeter end portion 33B.

The first and second perimeter end portions 33A and 33B include protrusion patterns 33AA and 33BA, which protrude from the cap 70 in plan view.

The protrusion pattern 33AA of the first perimeter end portion 33A extends in the Y-direction from the first perimeter end portion 33A toward the first substrate side surface 23 in plan view. The protrusion pattern 33AA extends from the first perimeter end portion 33A to the first substrate side surface 23 of the substrate 20. The protrusion pattern 33BA of the second perimeter end portion 33B extends in the Y-direction from the second perimeter end portion 33B toward the first substrate side surface 23 in plan view. The protrusion pattern 33BA extends from the second perimeter end portion 33B to the first substrate side surface 23. In plan view, the two protrusion patterns 33AA and 33BA are parallel to each other.

In the example of FIG. 4, the width dimensions WP and WQ of the two protrusion patterns 33AA and 33BA are less than the width dimension WA of the adhesion pattern 33. The width dimensions WP and WQ of the protrusion patterns 33AA and 33BA are equal to each other. The length dimensions LP and LQ of the protrusion patterns 33AA and 33BA are less than the width dimension WA of the adhesion pattern 33. The width dimensions WP and WQ and the length dimensions LP and LQ of the protrusion patterns 33AA and 33BA may be modified.

The width dimensions WP and WQ of the protrusion patterns 33AA and 33BA are dimensions in a direction perpendicular to the direction in which the protrusion patterns 33AA and 33BA extend in plan view. In the example shown in FIG. 4, the width dimensions WP and WQ are the dimensions of the protrusion patterns 33AA and 33BA in the Y-direction. The length dimensions LP and LQ of the protrusion patterns 33AA and 33BA are the dimensions in the direction in which the protrusion patterns 33AA and 33BA extend in plan view. In the example shown in FIG. 4, the length dimensions LP and LQ are the dimensions of the protrusion patterns 33AA and 33BA in the X-direction. The length dimensions LP and LQ are defined as the distance between the first split pattern 35A (second split pattern 35B) and the first substrate side surface 23 in the X-direction in plan view.

A curved portion 33C is formed at a corner section of the first perimeter end portion 33A on the side opposite to the protrusion pattern 33AA in the X-direction. A curved portion 33D is formed at a corner section of the second perimeter end portion 33B on the side opposite to the protrusion pattern 33BA in the X-direction. The curved portions 33C and 33D may be replaced by inclined portions. Also, the curved portions 33C and 33D may be omitted.

In plan view, the adhesion pattern 33 (first pattern 35) is not formed in the section between the first and second perimeter end portions 33A and 33B in the Y-direction, so that the substrate surface 21 of the substrate 20 is exposed. The distance in the Y-direction of the section in which the substrate surface 21 is exposed between the first and second perimeter end portions 33A and 33B (hereinafter referred to as separation distance D), may be greater than the distance between the first pattern 35 and the wire connection electrode 32AD in the X-direction. The separation distance D may be greater than the thickness dimension of the adhesion pattern 33. The separation distance D may be greater than the width dimensions WP and WQ of the protrusion patterns 33AA and 33BA. The separation distance D may be greater than the length dimensions LP and LQ of the protrusion patterns 33AA and 33BA. The separation distance D may be less than or equal to the width dimension WA of the adhesion pattern 33. In one example, the separation distance D is less than the width dimension WA of the adhesion pattern 33. In one example, the separation distance D is greater than the thickness dimension of the adhesion pattern 33. In one example, the separation distance D may be 50 μm or more and 500 μm or less. The size of the separation distance D may be modified.

### Side Structure of Semiconductor Light Emitting Device

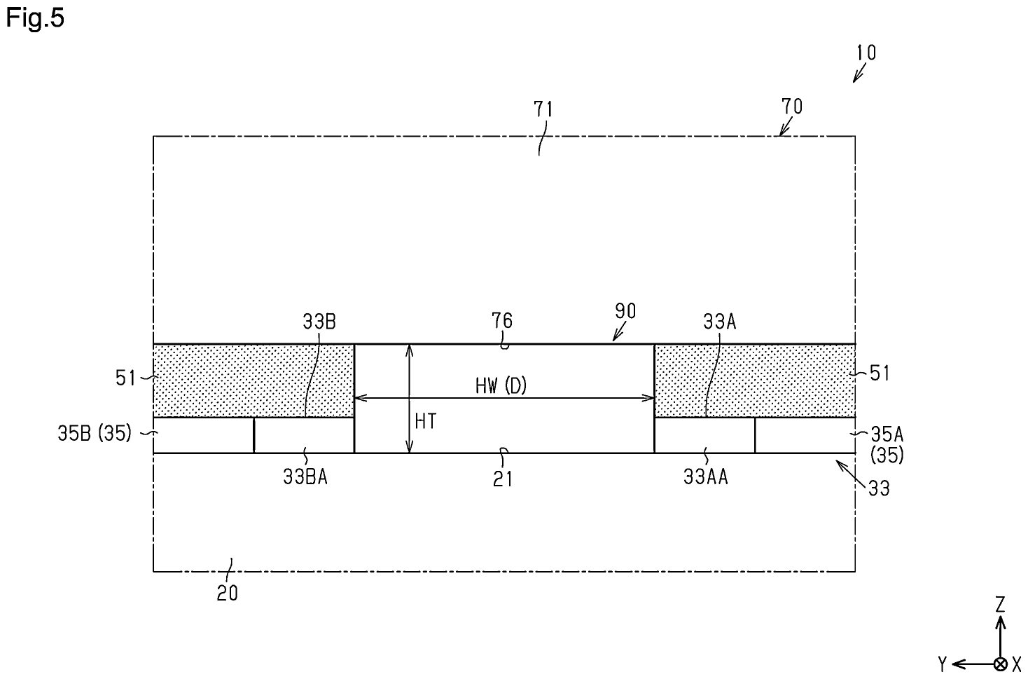

FIG. 5 shows a side structure as viewed from the side corresponding to the first side wall 71 of the cap 70 in a state in which the first adhesive 51 bonds the cap 70 to the adhesion pattern 33. FIG. 5 shows a side structure in which a second adhesive 52, which will be described below, is omitted.

As shown in FIG. 5, the semiconductor light emitting device 10 includes a connecting portion 90, which connects the inside and the outside of the cap 70 to each other. The connecting portion 90 laterally extends through at least the adhesion pattern 33 in plan view. That is, the connecting portion 90 may be considered as a through-hole laterally extending through at least the adhesion pattern 33 in plan view.

The connecting portion 90 extends through the adhesion pattern 33 in the width direction and splits the adhesion pattern 33 in the length direction of the adhesion pattern 33. In this embodiment, the connecting portion 90 is provided in the first pattern 35 of the adhesion patterns 33. Thus, the connecting portion 90 extends through the first pattern 35 in the X-direction, which is the width direction of the first pattern 35, and splits the first pattern 35 in the Y-direction, which is the length direction of the first pattern 35. More specifically, the first and second perimeter end portions 33A and 33B of the adhesion pattern 33 are spaced apart and opposed to each other in the Y-direction, so that the adhesion pattern 33 includes a section that laterally extends through the adhesion pattern 33 in plan view. In this embodiment, the term laterally refers to the width direction of the first pattern 35, specifically the X-direction. The first pattern 35 forms a section of the adhesion pattern 33 that extends in the transverse direction. As such, it may be considered that the connecting portion 90 is provided in a section of the adhesion pattern 33 that extends in the transverse direction.

The side wall of the cap 70 that is opposed to the first pattern 35 is the first side wall 71. Since the light transmission surface of the cap 70 is formed by the fourth side wall 74, the first side wall 71 differs from the light transmission surface. That is, the connecting portion 90 is provided in a side wall of the cap 70 that is different from the light transmission surface (the first side wall 71 in this embodiment). In other words, the connecting portion 90 is provided in a section of the adhesion pattern 33 that is different from the section corresponding to the light transmission surface.

In one example, sections of the first adhesive 51 are spaced apart from each other at the first and second perimeter end portions 33A and 33B. That is, the first adhesive 51 is split in the Y-direction, for example. In this manner, the connecting portion 90 is formed by the substrate surface 21 between the first and second perimeter end portions 33A and 33B of the adhesion pattern 33 in the Y-direction, the opening end surface 76 of the first side wall 71 of the cap 70, which is opposed to the substrate surface 21 in the Z-direction, the first and second perimeter end portions 33A and 33B, and the sections of the first adhesive 51 that are on the first and second perimeter end portions 33A and 33B and spaced apart from each other in the Y-direction.

The opening dimension HW of the connecting portion 90 is the dimension in the width direction of the connecting portion 90 as viewed from the X-direction. In the present embodiment, the opening dimension HW is defined by the distance in the Y-direction between the first and second perimeter end portions 33A and 33B of the adhesion pattern 33. That is, the opening dimension HW of the connecting portion 90 is equal to the separation distance D between the first and second perimeter end portions 33A and 33B. As such, the connecting portion 90 may be considered as the region between the first and second perimeter end portions 33A and 33B in the Y-direction in plan view. Also, in this embodiment, the opening dimension HW of the connecting portion 90 is less than the width dimension WA of the adhesion pattern 33 (see FIG. 2).

The opening thickness dimension HT of the connecting portion 90 is defined by the distance in the Z-direction between the substrate surface 21 of the substrate 20 and the opening end surface 76 of the first side wall 71. As such, the opening thickness dimension HT of the connecting portion 90 is greater than the thickness dimension of the adhesion pattern 33. More specifically, the opening thickness dimension HT of the connecting portion 90 is equal to the sum of the thickness dimension of the adhesion pattern 33 and the thickness dimension of the first adhesive 51. In this embodiment, the opening thickness dimension HT of the connecting portion 90 is less than the opening dimension HW. The opening dimension HW and the opening thickness dimension HT of the connecting portion 90 may be modified.

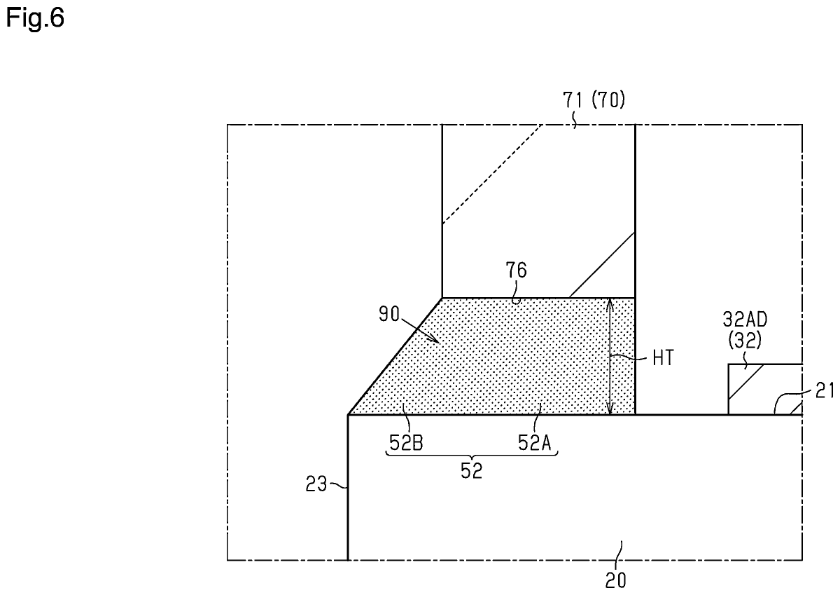

FIG. 6 shows an enlarged view of the first side wall 71 of the cap 70 and its surrounding area in the cross-sectional structure of the semiconductor light emitting device 10 shown in FIG. 3.

As shown in FIG. 6, the second adhesive 52 is placed in the connecting portion 90. Thus, it may be considered that the connecting portion 90 is filled with the second adhesive 52. That is, the first adhesive 51, the second adhesive 52, the adhesion pattern 33, and the cap 70 form a sealed space S (see FIG. 3). In one example, the second adhesive 52 may be an adhesive of a type different from the first adhesive 51. In this case, the second adhesive 52 may be an adhesive having a lower viscosity than the first adhesive 51, for example. The viscosity of the adhesive is measured before the adhesive is cured. In one example, the viscosity may be measured using a rotational viscometer (such as a Brookfield type single cylinder rotational viscometer). Examples of a test method include the test method specified in Japanese Industrial Standard JIS6833-1 2008 (Adhesives—General testing methods).

The second adhesive 52 is in contact with the section of the substrate surface 21 of the substrate 20 that defines the connecting portion 90. The second adhesive 52 includes a thick adhesion portion 52A having a greater thickness than the first adhesive 51. The thick adhesion portion 52A is a section occupying the connecting portion 90. In other words, the thick adhesion portion 52A is a section that bonds the substrate surface 21 to the opening end surface 76 of the first side wall 71 facing the substrate surface 21. Accordingly, the thickness dimension of the thick adhesion portion 52A is equal to the opening thickness dimension HT of the connecting portion 90. The thickness dimension of the thick adhesion portion 52A is therefore greater than the thickness of the first adhesive 51. Also, the width dimension of the thick adhesion portion 52A is equal to the opening dimension HW of the connecting portion 90 (see FIG. 5). The width dimension of the thick adhesion portion 52A is therefore less than the width dimension WA of the adhesion pattern 33 (see FIG. 2).

The second adhesive 52 includes a protrusion portion 52B, which is continuous with the thick adhesion portion 52A and protrudes from the first side wall 71 of the cap 70 in plan view. The protrusion portion 52B may be formed between the protrusion patterns 33AA and 33BA (see FIG. 4) of the adhesion pattern 33 in the Y-direction. In one example, the dimension of the protrusion portion 52B in the X-direction is equal to the dimension of the protrusion patterns 33AA and 33BA in the X-direction. The protrusion portion 52B is formed such that its thickness becomes smaller at locations farther from the first side wall 71 in the X-direction, for example. In plan view, the protrusion portion 52B extends from the first side wall 71 to the first substrate side surface 23 in the X-direction.

### Method for Manufacturing Semiconductor Light Emitting Device

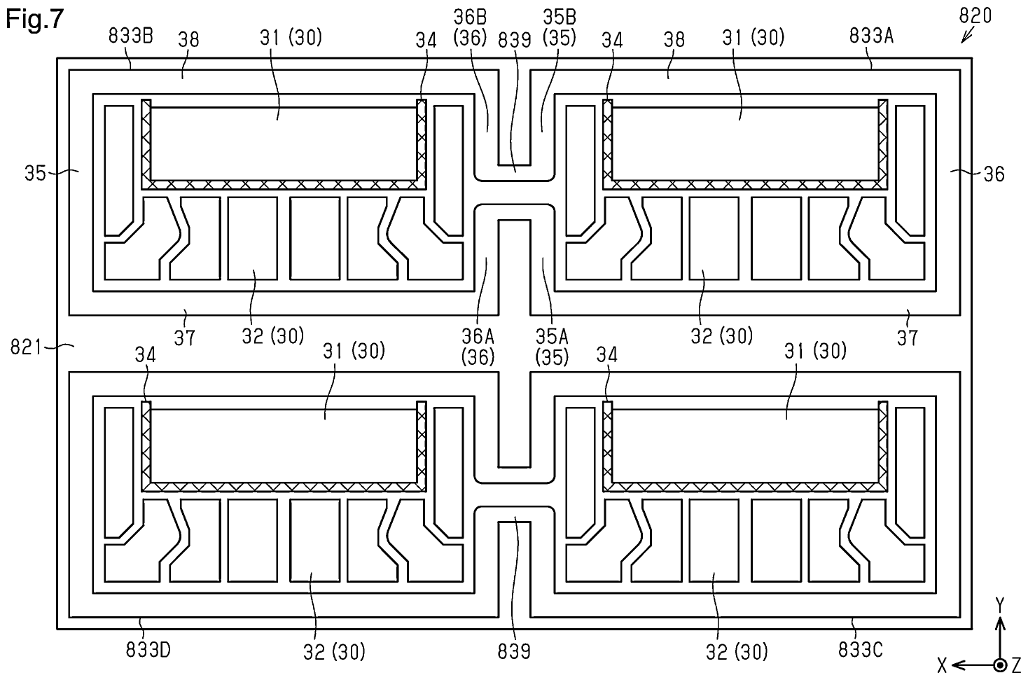

Referring to FIGS. 7 to 13, an example of a method for manufacturing the semiconductor light emitting device 10 is now described.

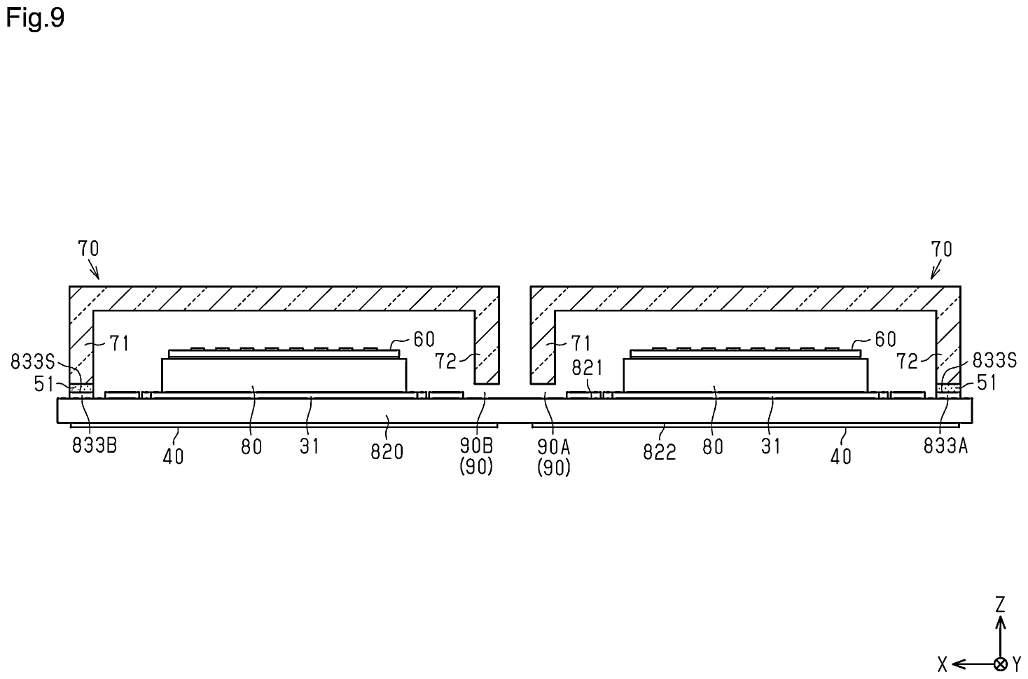

FIGS. 7, 8, and 13 show the planar structure of a substrate 820. FIGS. 9 to 12 show the end structure of the substrate 820 taken along an XZ plane. To facilitate the understanding of the drawings, the wires W are omitted in FIGS. 9 to 12.

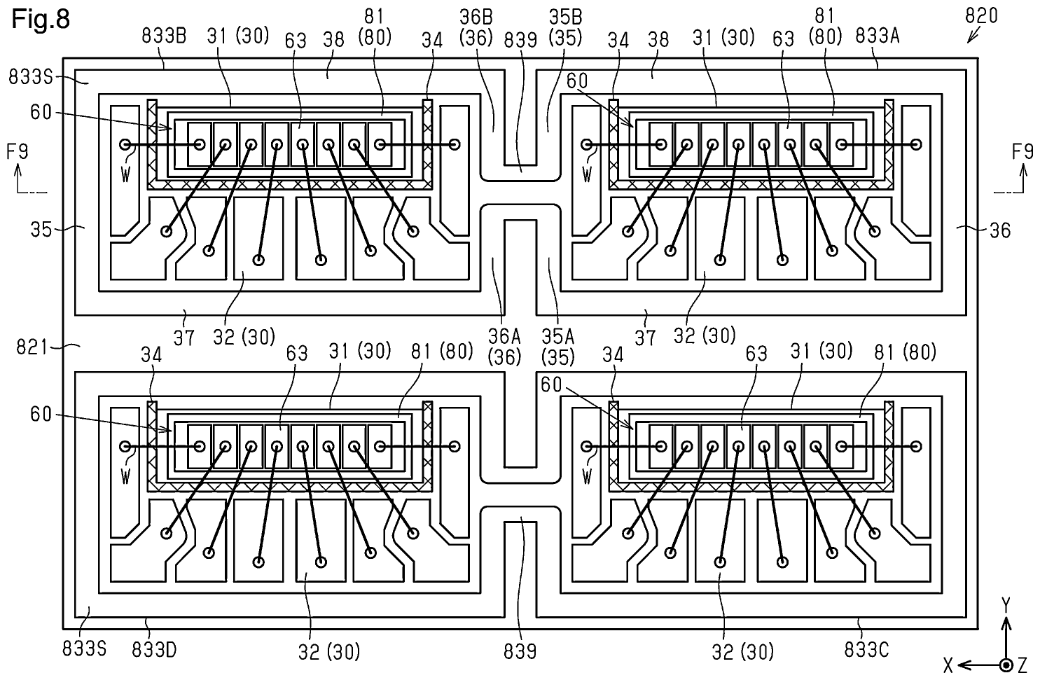

As shown in FIGS. 7 and 8, the method for manufacturing the semiconductor light emitting device 10 mainly includes the steps of preparing a substrate 820, placing a submount substrate 80 on the substrate 820, placing an edge-emitting light emitting element 60 on the submount substrate 80, and forming wires W1A to W4A and W1B to W4B (see FIG. 2). In the following description, the wires W1A to W4A and W1B to W4B are simply referred to as wires W.

FIG. 7 shows the planar structure of the substrate 820 in the step of preparing the substrate 820.

As shown in FIG. 7, in the step of preparing the substrate 820, the substrate 820 including a substrate surface 821 and a substrate back surface 822 (see FIG. 9) opposite to the substrate surface 821 is prepared. Multiple surface electrodes 30, adhesion patterns 833A to 833D, and resist patterns are formed on the substrate surface 821 of the substrate 820. Multiple back electrodes 40 (see FIG. 3) are formed on the substrate back surface 822. In one example, the substrate 820 is configured to form four semiconductor light emitting devices 10. Four adhesion patterns 833A to 833D are therefore formed on the substrate 820.

In plan view, the adhesion patterns 833A to 833D each have a frame shape having a predetermined width and extending in a length direction perpendicular to the width. In one example, the adhesion patterns 833A to 833D have a rectangular frame shape having a longitudinal direction in the X-direction and a transverse direction in the Y-direction in plan view.

The adhesion patterns 833A and 833B are arranged in the X-direction. The adhesion patterns 833C and 833D are arranged in the X-direction. The adhesion patterns 833A and 833B and the adhesion patterns 833C and 833D are arranged in the Y-direction. More specifically, the adhesion patterns 833A and 833C are arranged in the Y-direction. The adhesion patterns 833B and 833D are arranged in the Y-direction. The adhesion patterns 833A and 833C correspond to “a first adhesion pattern,” and the adhesion patterns 833B and 833D correspond to “a second adhesion pattern.” The X-direction corresponds to “a first direction” and the Y-direction corresponds to “a second direction.” The Z-direction corresponds to “the thickness direction of the substrate 820.” As such, the expression “in plan view” refers to “as viewed from the thickness direction of the substrate 820.”

The adhesion patterns 833A and 833B arranged in the X-direction are connected to each other. More specifically, the adhesion patterns 833A and 833B include two coupling portions 839 formed between the adhesion patterns 833A and 833B and spaced apart from each other in the Y-direction. The coupling portions 839 connect the adhesion pattern 833A to the adhesion pattern 833B in the X-direction. Each coupling portion 839 extends in the X-direction. The width dimension of each coupling portion 839 is less than the width dimension of the adhesion patterns 833A and 833B. The width dimension of each coupling portion 839 is a dimension in a direction perpendicular to the direction in which the coupling portion 839 extends in plan view. In this embodiment, the width dimension of each coupling portion 839 is the dimension of the coupling portion 839 in the Y-direction. Furthermore, the width dimension of the adhesion patterns 833A and 833B is the same as the width dimension WA of the adhesion pattern 33 (see FIG. 2).

The coupling portions 839 are formed in sections of the adhesion patterns 833A and 833B that extend in the transverse direction. These sections are separated in the Y-direction by the coupling portions 839. The substrate surface 821 of the substrate 820 is exposed in the section between the coupling portions 839 in the Y-direction. Accordingly, the adhesion patterns 833A and 833B include sections that laterally extend through sections extending in the transverse direction. In one example, the length dimension (dimension in the X-direction) of each coupling portion 839 is greater than the dimension between the two coupling portions 839 in the Y-direction. That is, the distance between the first pattern 35 of the adhesion pattern 833A and the second pattern 36 of the adhesion pattern 833B in the X-direction is greater than the dimension between the two coupling portions 839 in the Y-direction.

The adhesion patterns 833A and 833B each correspond to the adhesion pattern 33 shown in FIG. 2. As such, the adhesion patterns 833A and 833B each include first to fourth patterns 35 to 38. Thus, it may be considered that the two coupling portions 839 are formed to connect the first pattern 35 of the adhesion pattern 833A to the second pattern 36 of the adhesion pattern 833B. Furthermore, it may be considered that the second pattern 36 of the adhesion pattern 833B includes the first and second split patterns 36A and 36B, in the same manner as the first pattern 35 shown in FIG. 2.

The adhesion patterns 833C and 833D adjacent in the X-direction are also connected to each other in the same manner. The connection structure of the adhesion patterns 833C and 833D is the same as that of the adhesion patterns 833A and 833B. Detailed description is therefore omitted.

As shown in FIG. 8, in the step of placing submount substrates 80 on the substrate 820, a first conductive bonding material (not shown) is first applied to each element surface electrode 31. The submount substrates 80 are placed on the first conductive bonding material. That is, in this step, the submount substrates 80 are die-bonded to the respective element surface electrodes 31. The first conductive bonding material is a die bonding material, which may be a solder paste or a silver paste, for example.

In the subsequent step of placing the edge-emitting light emitting elements 60 on the submount substrates 80, a second conductive bonding material is first applied to the front surface 81 of each submount substrate 80. The edge-emitting light emitting element 60 is then placed on the second conductive bonding material. That is, in this step, the edge-emitting light emitting element 60 is die-bonded to the submount substrate 80. The second conductive bonding material is a die bonding material, which may be a solder paste or a silver paste, for example. The first and second conductive bonding materials may be the same or different. In this manner, the edge-emitting light emitting elements 60 are arranged within the frames of the respective adhesion patterns 833A to 833D on the substrate 820. In other words, the adhesion patterns 833A to 833D are formed so as to surround the corresponding edge-emitting light emitting elements 60 in plan view.

In this embodiment, after the edge-emitting light emitting element 60 is placed on the submount substrate 80, the first and second conductive bonding materials are solidified at the same time. More specifically, the first and second conductive bonding materials are solidified by heating and then cooling them. As a result, the first conductive bonding material bonds the element surface electrode 31 and the submount substrate 80, and the second conductive bonding material bonds the submount substrate 80 and the edge-emitting light emitting element 60. The first and second conductive bonding materials may be solidified separately. In one example, in the step of placing the submount substrate 80 on the substrate 820, the element surface electrode 31 and the submount substrate 80 are bonded by solidifying the first conductive bonding material. Then, in the step of placing the edge-emitting light emitting element 60 on the submount substrate 80, the submount substrate 80 and the edge-emitting light emitting element 60 are bonded by solidifying the second conductive bonding material.

In the subsequent step of forming wires W, wires W are formed so as to individually connect the element electrodes 63 of each edge-emitting light emitting element 60 and the wire connection electrodes 32 using a wire bonding device. The element electrodes 63 are thus electrically connected to the respective wire connection electrodes 32.

As shown in FIGS. 9 to 13, the method for manufacturing the semiconductor light emitting device 10 includes the steps of applying the first adhesive 51 to each of the adhesion patterns 833A to 833D, accommodating the edge-emitting light emitting elements 60 by placing caps 70 on the first adhesive 51, bonding the caps 70 to the adhesion patterns 833A to 833D by curing the first adhesive 51, filling connecting portions 90 with the second adhesive 52, curing the second adhesive 52, and performing singulation. These steps may be performed after the step of forming wires W, for example.

FIG. 9 shows the step of applying the first adhesive 51 to the adhesion patterns 833A and 833B, and the step of accommodating the edge-emitting light emitting elements 60 by placing the caps 70 on the first adhesive 51. FIG. 9 shows the end structure taken along line F9-F9 in FIG. 8.

As shown in FIG. 9, the step of applying the first adhesive 51 to the adhesion patterns 833A and 833B applies the first adhesive 51 over the entire pattern surfaces 833S of the adhesion patterns 833A and 833B using a dispenser, for example. In one example, the first adhesive 51 is a thermosetting adhesive. The first adhesive 51 is not applied to the pattern surface of the coupling portions 839 (see FIG. 7), for example. Although not shown, the first adhesive 51 is applied to the pattern surfaces 833S of the adhesion patterns 833C and 833D in the same manner.

In the subsequent step of accommodating the edge-emitting light emitting elements 60 by placing caps 70 on the first adhesive 51, a cap 70 is placed on the first adhesive 51 on the adhesion pattern 833A, and another cap 70 is placed on the first adhesive 51 on the adhesion pattern 833B. The cap 70 corresponding to the adhesion pattern 833A corresponds to “a first cap,” and the other cap 70 corresponding to the adhesion pattern 833B corresponds to “a second cap.”

When the cap 70 is placed on the first adhesive 51 on the adhesion pattern 833A, sections of the first adhesive 51 and the adhesion pattern 833A are separated in the Y-direction at the coupling portions 839 (see FIG. 8), forming a connecting portion 90, which connects the inside and the outside of the cap 70 to each other. That is, the internal space of the cap 70 is continuous with the outside of the cap 70 through the connecting portion 90. The connecting portion 90 that is formed by the adhesion pattern 833A, the first adhesive 51 on the adhesion pattern 833A, the cap 70 on the first adhesive 51, and the substrate surface 21 corresponds to “a first connecting portion.” Hereinafter, for convenience, the connecting portion 90 corresponding to the adhesion pattern 833A is referred to as “a first connecting portion 90A.”

When the cap 70 is placed on the first adhesive 51 on the adhesion pattern 833B, the first adhesive 51 and the adhesion pattern 833B are split in the Y-direction at the coupling portions 839, forming a connecting portion 90, which connects the inside and the outside of the cap 70 to each other. That is, the internal space of the cap 70 is continuous with the outside of the cap 70 through the connecting portion 90. The connecting portion 90 that is formed by the adhesion pattern 833B, the first adhesive 51 on the adhesion pattern 833B, the cap 70 on the first adhesive 51, and the substrate surface 21 corresponds to “a second connecting portion.” Hereinafter, for convenience, the connecting portion 90 corresponding to the adhesion pattern 833B is referred to as “a second connecting portion 90B.”

The first and second connecting portions 90A and 90B are formed between the two coupling portions 839, which connect the adhesion pattern 833A to the adhesion pattern 833B, in the Y-direction. Thus, the first and second connecting portions 90A and 90B are located at the same position in the Y-direction. Also, the opening dimension of the first connecting portion 90A is equal to the opening dimension of the second connecting portion 90B. Furthermore, the opening thickness dimension of the first connecting portion 90A is equal to the opening thickness dimension of the second connecting portion 90B. The opening dimension of each of the first and second connecting portions 90A and 90B correspond to the opening dimension HW of the connecting portion 90 (see FIG. 5). The opening thickness dimension of each of the first and second connecting portions 90A and 90B corresponds to the opening thickness dimension HT of the connecting portion 90 (see FIG. 5).

In this manner, in the step of bonding the cap 70 to each of the adhesion patterns 833A and 833B, the first connecting portion 90A is formed by the adhesion pattern 833A and the cap 70 on the adhesion pattern 833A, and the second connecting portion 90B is formed by the adhesion pattern 833B and the cap 70 on the adhesion pattern 833B.

The distance between the first pattern 35 of the adhesion pattern 833A and the second pattern 36 of the adhesion pattern 833B in the X-direction shown in FIG. 8 is greater than both the opening dimension of the first connecting portion 90A and the opening dimension of the second connecting portion 90B. As such, the distance between the cap 70 corresponding to the adhesion pattern 833A and the cap 70 corresponding to the adhesion pattern 833B in the X-direction is greater than both the opening dimension of the first connecting portion 90A and the opening dimension of the second connecting portion 90B.

Although not shown, a cap 70 is placed on the first adhesive 51 of each of the adhesion patterns 833C and 833D to accommodate the edge-emitting light emitting element 60 in the same manner. As such, in the step of bonding the cap 70 to each of the adhesion patterns 833C and 833D, a connecting portion 90 (first connecting portion) is formed by the adhesion pattern 833C and the cap 70 on the adhesion pattern 833C, and a connecting portion (second connecting portion) is formed by the adhesion pattern 833D and the cap 70 on the adhesion pattern 833D.

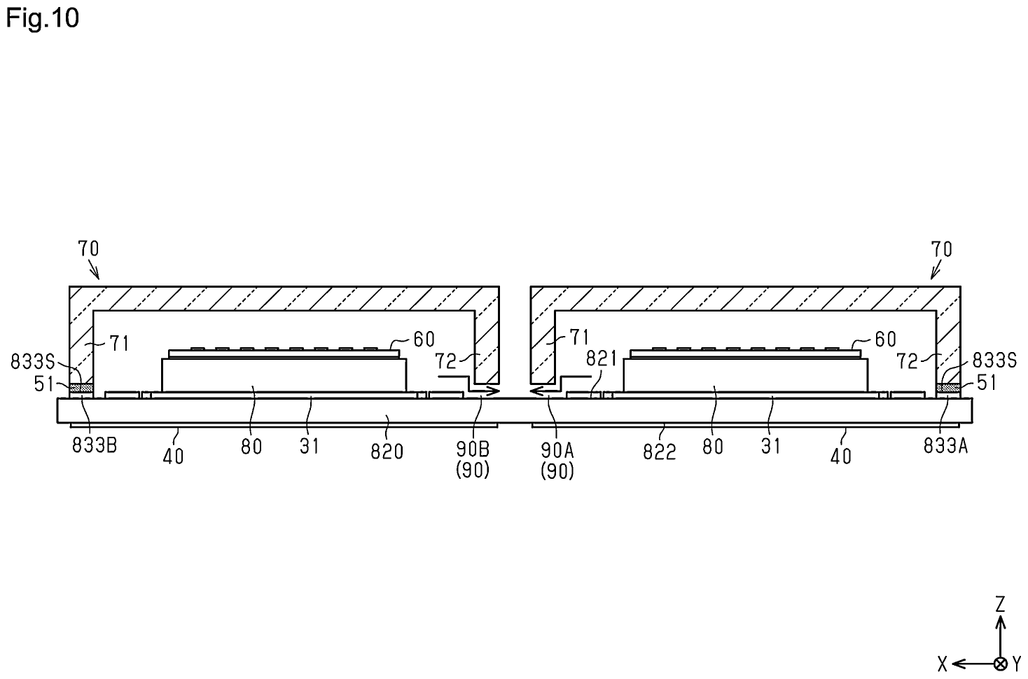

As shown in FIG. 10, in the subsequent step of bonding the caps 70 to the adhesion patterns 833A and 833B by curing the first adhesive 51, the first adhesive 51 is thermally cured. As a result, the caps 70 are bonded to the respective adhesion patterns 833A and 833B.

To thermally cure the first adhesive 51, the substrate 820 is placed in a high-temperature furnace, so that the substrate 820 is also heated. At this time, the air inside the caps 70 corresponding to the adhesion patterns 833A and 833B is also heated and increases in volume. However, the first and second connecting portions 90A and 90B allow the expanded air to move to the outside of the caps 70. This limits an excessive increase in the pressure in the caps 70 corresponding to the adhesion patterns 833A and 833B. Also, the gas generated by the outgassing of the first adhesive 51 applied to the adhesion patterns 833A and 833B, which would otherwise remain inside the caps 70 corresponding to the adhesion patterns 833A and 833B, is discharged to the outside of the caps 70 through the first and second connecting portions 90A and 90B. This limits an excessive increase in the pressure in the caps 70 corresponding to the adhesion patterns 833A and 833B. Although not shown, this step also bonds the caps 70 to the adhesion patterns 833C and 833D by curing the first adhesive 51.

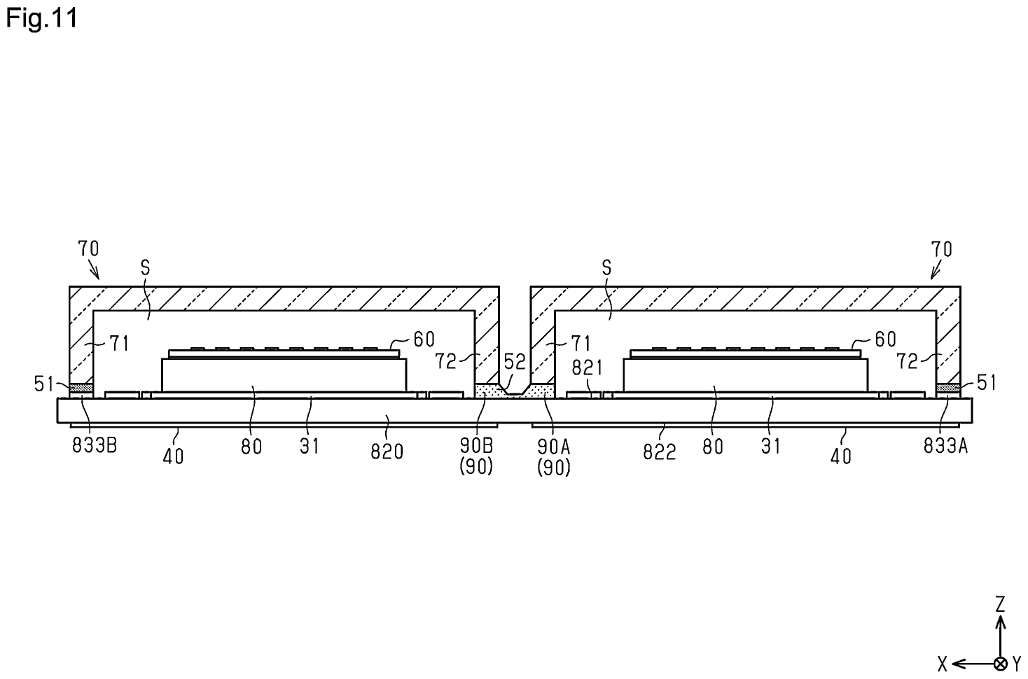

As shown in FIG. 11, in the subsequent step of filling the connecting portion 90 with the second adhesive 52, the second adhesive 52 is applied in droplets to the substrate surface 821 of the substrate 820 between the coupling portions 839 (FIG. 8) connecting the adhesion patterns 833A and 833B using a dispenser, for example. At this time, the coupling portions 839 limit movement of the second adhesive 52 in the Y-directions and cause the second adhesive 52 to move along the perimeters of the adhesion patterns 833A and 833B. This facilitates the entry of the second adhesive 52 into the first and second connecting portions 90A and 90B from the section between the coupling portions 839. As a result, both the first and second connecting portions 90A and 90B are filled with the second adhesive 52.

The diameter of the nozzle of the dispenser used in this embodiment to apply the second adhesive 52 in droplets to the section between the two coupling portions 839 may be about 100 μm, for example. As such, the distance between the two coupling portions 839 in the Y-direction is preferably 100 μm or more. The distance between the two coupling portions 839 in the Y-direction is equal to the opening dimension of the first connecting portion 90A and the opening dimension of the second connecting portion 90B. The opening dimensions of the first and second connecting portions 90A and 90B correspond to the opening dimension HW of the connecting portions 90. Accordingly, in this embodiment, the opening dimension HW of the connecting portion 90 is preferably 100 μm or more. The opening dimension HW of the connecting portion 90 may be modified according to the diameter of the nozzle of the dispenser, for example.

Although not shown, the second adhesive 52 is also applied in droplets to the substrate surface 821 of the substrate 820 between the two coupling portions 839 connecting the adhesion patterns 833C and 833D using a dispenser, for example. As a result, the connecting portion 90 (first connecting portion) formed by the adhesion pattern 833C and the cap 70 on the adhesion pattern 833C, and the connecting portion 90 (second connecting portion) formed by the adhesion pattern 833D and the cap 70 on the adhesion pattern 833D are both filled with the second adhesive 52.

The second adhesive 52 may be an adhesive of a type different from the first adhesive 51. In one example, an adhesive having a lower viscosity than the first adhesive 51 may be used as the second adhesive 52.

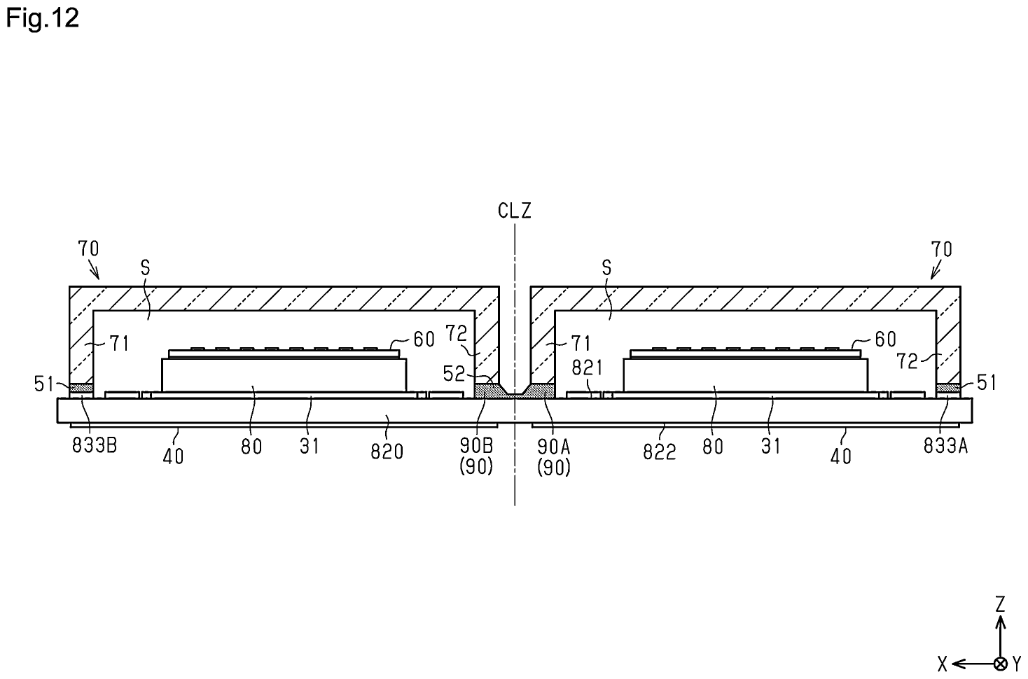

As shown in FIG. 12, in the subsequent step of curing the second adhesive 52, the second adhesive 52 is thermally cured. The method of thermal curing of the second adhesive 52 is the same as the method of thermal curing of the first adhesive 51. Thus, when the second adhesive 52 is thermally cured, the air inside the caps 70 is also heated. Since the first and second connecting portions 90A and 90B are filled with the second adhesive 52, the pressure inside the caps 70 corresponding to the adhesion patterns 833A and 833B becomes high. However, since the caps 70 are bonded to the adhesion patterns 833A and 833B (833C and 833D) by the first adhesive 51, the caps 70 are unlikely to tilt relative to the respective adhesion patterns 833A and 833B.

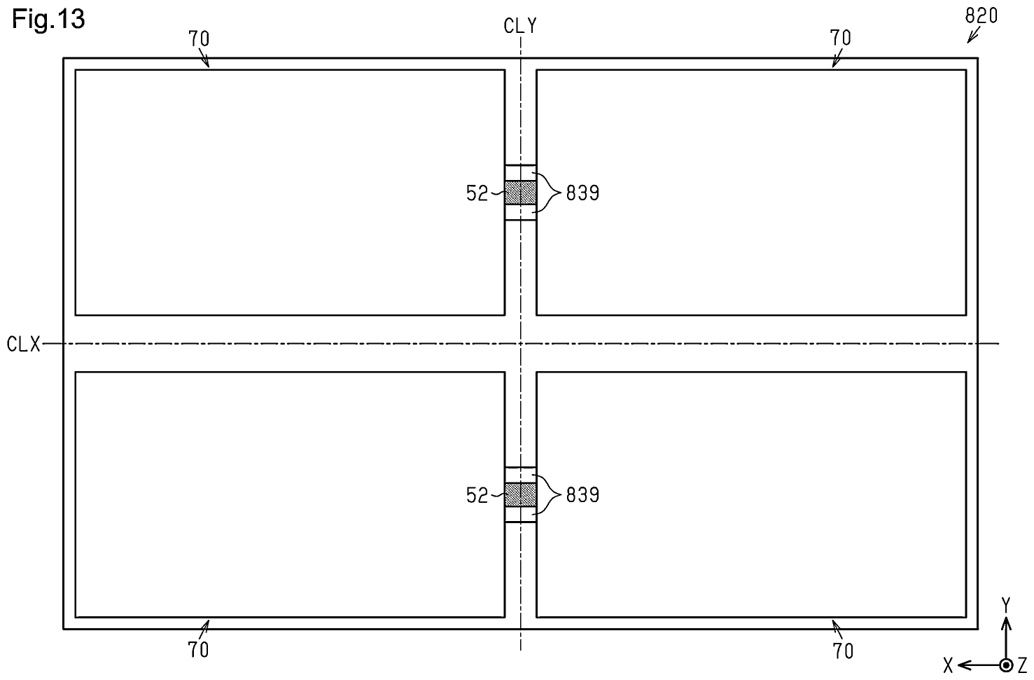

In the subsequent singulation step, the substrate 820 is cut along cutting lines CLZ shown in FIG. 12 using a dicing blade, for example. As shown in FIG. 13, the substrate 820 is cut along cutting lines CLX and CLY in plan view. The cutting line CLX extends in the X-direction, and the cutting line CLY extends in the Y-direction. The substrate 820 is thus cut in the X-direction and also in the Y-direction. As a result, four substrates 20 are formed from the substrate 820.

The cutting line CLY crosses the second adhesive 52 and the coupling portions 839. As such, when the substrate 820 is cut along the cutting line CLY, the second adhesive 52 and the coupling portions 839 are also cut. This forms protrusion portions 52B of the second adhesive 52 and the protrusion patterns 33AA and 33BA (see FIG. 4). That is, an adhesion pattern 33 (see FIG. 2) is formed from each of the adhesion patterns 833A to 833D (see FIG. 8). In this manner, the singulation step includes the step of cutting the second adhesive 52, the coupling portions 839, and the substrate 820 in the Y-direction.

The semiconductor light emitting device 10 shown in FIGS. 1 to 6 is manufactured through the above steps.

Also, although not shown, through the above steps, a semiconductor light emitting device 10 is manufactured that includes a connecting portion 90 (second connecting portion 90B) that is located between the second side wall 72 of the cap 70 and the substrate 20 and filled with the second adhesive 52. In this semiconductor light emitting device 10, the protrusion patterns 33AA and 33BA shown in FIG. 2 extend toward the second substrate side surface 24 of the substrate 20. That is, the above steps manufacture a semiconductor light emitting device 10 that includes protrusion patterns 33AA and 33BA extending toward the first substrate side surface 23, and a semiconductor light emitting device 10 that includes protrusion patterns 33AA and 33BA extending toward the second substrate side surface 24.

### Operation

Operation of the semiconductor light emitting device 10 is now described.

When the first adhesive 51 between the pattern surface 33S of the adhesion pattern 33 and the opening end surface 76 of the cap 70 is thermally cured, the air in the internal space of the cap 70 expands as the temperature of the internal space increases. However, the connecting portion 90, which is formed to connect the inside and the outside of the cap 70 to each other, allows the expanded air in the internal space to move to the outside of the cap 70 through the connecting portion 90. Accordingly, the thermal curing of the first adhesive 51 is unlikely to excessively increase the pressure in the cap 70. This limits tilting of the cap 70 relative to the substrate surface 21 of the substrate 20, which would otherwise be caused by an excess increase in pressure in the cap 70.

Also, the gas generated by the outgassing of the first adhesive 51 in the cap 70 tends to increase the pressure in the cap 70. However, since the connecting portion 90 allows the air in the cap 70 to move to the outside of the cap 70 through the connecting portion 90, the pressure in the cap 70 is unlikely to become excessively high.

If the connecting portion 90 is left as it is, minute foreign matter such as water droplets and dust would enter the cap 70 through the connecting portion 90. In this respect, the connecting portion 90 of the present embodiment is filled with the second adhesive 52. This limits entry of foreign matter into the cap 70. The second adhesive 52 is also solidified by thermal curing. However, since the cap 70 is bonded to the adhesion pattern 33 by the first adhesive 51, the cap 70 is unlikely to tilt relative to the substrate surface 21 even if the internal pressure of the cap 70 increases due to the thermal curing of the second adhesive 52.

### Advantageous Effects

The semiconductor light emitting device 10 has the following advantageous effects.

(1) The semiconductor light emitting device 10 includes a substrate 20, an edge-emitting light emitting element 60 placed on the substrate 20, a cap 70 that accommodates the edge-emitting light emitting element 60, an adhesion pattern 33 disposed on the substrate 20 so as to surround the edge-emitting light emitting element 60 in plan view, a first adhesive 51 bonding the cap 70 to a pattern surface 33S of the adhesion pattern 33, a connecting portion 90 extending laterally through at least the adhesion pattern 33 in plan view to connect the inside of the cap 70 and the outside of the cap 70 to each other, and a second adhesive 52 with which the connecting portion 90 is filled.

According to this configuration, gas inside the cap 70 (such as air and gas generated by outgassing of the first adhesive 51) can be discharged to the outside of the cap 70 through the connecting portion 90. This limits tilting of the cap 70 relative to the substrate 20, which would otherwise be caused by an excess increase in pressure in the cap 70. Also, since the connecting portion 90 is filled with the second adhesive 52, foreign matter is unlikely to enter the cap 70.

(2) The adhesion pattern 33 has a frame shape having a predetermined width and extending in a length direction perpendicular to the width. The connecting portion 90 extends through the adhesion pattern 33 in the width direction and splits the adhesion pattern 33 in the length direction of the adhesion pattern 33.

According to this configuration, the adhesion pattern 33 is split in the length direction, facilitating splitting in the length direction of the first adhesive 51 on the pattern surface 33S of the adhesion pattern 33. Thus, the connecting portion 90 is not filled with the first adhesive 51, ensuring the connection between the inside and the outside of the cap 70.

(3) The opening dimension HW of the connecting portion 90 is equal to or less than the width dimension WA of the adhesion pattern 33.

According to this configuration, a smaller opening dimension HW of the connecting portion 90 increases the area of the pattern surface 33S of the adhesion pattern 33. This increases the bonding strength between the cap 70 and the adhesion pattern 33 by the first adhesive 51.

(4) The adhesion pattern 33 has a rectangular frame shape in plan view. The cap 70 includes a light transmission surface at a position corresponding to one side of the adhesion pattern 33 in plan view. The connecting portion 90 is provided in a side of the adhesion pattern 33 that is different from the side corresponding to the light transmission surface.

According to this configuration, when applying the second adhesive 52 to the connecting portion 90, the second adhesive 52 may adhere to a side wall (the first side wall 71 in this embodiment) of the cap 70. However, since the connecting portion 90 is located at a position different from the light transmission surface, any adherence of the second adhesive 52 to the side wall of the cap 70 is unlikely to affect the light emitted from the edge-emitting light emitting element 60.

(5) The adhesion pattern 33 includes the first and second perimeter end portions 33A and 33B, which define the connecting portion 90. The first and second perimeter end portions 33A and 33B include the protrusion patterns 33AA and 33BA, which protrude from the cap 70 in plan view.

According to this configuration, even if the second adhesive 52 with which the connecting portion 90 is filled protrudes from the cap 70 in plan view, the protrusion patterns 33AA and 33BA limit spreading of the second adhesive 52.

(6) The width dimensions WP and WQ of the protrusion patterns 33AA and 33BA are less than the width dimension WA of the adhesion pattern 33.

According to this configuration, the smaller width dimensions WP and WQ of the protrusion patterns 33AA and 33BA allow the protrusion patterns 33AA and 33BA protruding from the cap 70 to be less noticeable. This improves the appearance of the semiconductor light emitting device 10.

(7) A method for manufacturing a semiconductor light emitting device 10 includes placing an edge-emitting light emitting element 60 on a substrate 820 having a substrate surface 821, applying a first adhesive 51 to an adhesion pattern 33 that surrounds the edge-emitting light emitting element 60 on the substrate 820 in plan view, accommodating the edge-emitting light emitting element 60 by placing a cap 70 on the first adhesive 51, and bonding the cap 70 to the adhesion pattern 33 by curing the first adhesive 51. In the step of bonding the cap 70 to the adhesion pattern 33, a connecting portion 90 extending laterally through at least the adhesion pattern 33 in plan view is defined to connect the inside of the cap 70 and the outside of the cap 70 to each other. The method also includes filling the connecting portion 90 with a second adhesive 52 after the step of bonding the cap 70 to the adhesion pattern 33 by curing the first adhesive 51.

According to this configuration, in the step of bonding the cap 70 to the adhesion pattern 33 by curing the first adhesive 51, gas inside the cap 70 (such as air and gas generated by outgassing of the first adhesive 51) can be discharged to the outside of the cap 70 through the connecting portion 90. This limits tilting of the cap 70 relative to the substrate 20, which would otherwise be caused by an excess increase in pressure in the cap 70. The connecting portion 90 is subsequently filled with the second adhesive 52, thereby limiting entry of foreign matter into the cap 70.

(8) The adhesion pattern 33 has a frame shape having a predetermined width and extending in a length direction perpendicular to the width in plan view. The connecting portion 90 extends through the adhesion pattern 33 in the width direction and splits the adhesion pattern 33 in the length direction of the adhesion pattern 33. The step of applying the first adhesive 51 to the adhesion pattern 33 includes applying the first adhesive 51 to the pattern surface 33S of the adhesion pattern 33 without applying the first adhesive 51 to the connecting portion 90.

According to this configuration, the adhesion pattern 33 is split in the length direction, facilitating splitting in the length direction of the first adhesive 51 on the pattern surface 33S of the adhesion pattern 33. Thus, the connecting portion 90 is not filled with the first adhesive 51, ensuring the connection between the inside and the outside of the cap 70.

(9) The adhesion pattern 33 includes adhesion patterns 833A and 833B arranged in the X-direction in plan view and two coupling portions 839, which are placed between the first and second adhesion patterns 833A and 833B in the X-direction, are spaced apart from each other in the Y-direction, and connect the first adhesion pattern 833A to the second adhesion pattern 833B in the X-direction. The connecting portion 90 includes a first connecting portion 90A that connects the inside of the cap 70 bonded to the adhesion pattern 833A and the outside of the cap 70 to each other, and a second connecting portion 90B that connects the inside of the cap 70 bonded to the adhesion pattern 833B and the outside of the cap 70 to each other. The step of applying the first adhesive 51 to the adhesion patterns 833A and 833B applies the first adhesive 51 to each of the pattern surfaces 833S of the adhesion patterns 833A and 833B. The step of accommodating the edge-emitting light emitting element 60 includes placing the cap 70 on the first adhesive 51 on the adhesion pattern 833A and placing the cap 70 on the first adhesive 51 on the adhesion pattern 833B. In the step of bonding the cap 70 to each of the adhesion patterns 833A and 833B, the first connecting portion 90A is formed by the adhesion pattern 833A and the cap 70, and the second connecting portion 90B is formed by the adhesion pattern 833B and the cap 70. The step of filling the connecting portion 90 with the second adhesive 52 includes applying the second adhesive 52 in droplets to the substrate surface 821 between the two coupling portions 839 to fill both the first and second connecting portions 90A and 90B with the second adhesive 52.

According to this configuration, the two coupling portions 839, which are spaced apart from each other in the Y-direction, connect the adhesion patterns 833A and 833B. Thus, placing the caps 70 on the first adhesive 51 on the adhesion pattern 833A and the first adhesive 51 on the adhesion pattern 833B form the first and second connecting portions 90A and 90B. That is, the first and second connecting portions 90A and 90B as two connecting portions can be simultaneously formed using the two coupling portions 839.

Also, the step of filling the connecting portions 90 with the second adhesive 52 includes applying the second adhesive 52 in droplets to the substrate surface 821 between the two coupling portions 839. This eliminates the need for separately introducing the second adhesive 52 into the first connecting portion 90A and the second connecting portion 90B. This simplifies the step of filling the connecting portions 90 with the second adhesive 52.

(10) The method for manufacturing the semiconductor light emitting device 10 further includes cutting the second adhesive 52, the coupling portions 839, and the substrate 820 in the Y-direction. The width dimension of the coupling portions 839 is less than the width dimension WA of the adhesion pattern 33. According to this configuration, the smaller width dimension of the coupling portions 839 facilitates the cutting of the coupling portions 839 together with the substrate 820.

(11) An adhesive having a lower viscosity than the first adhesive 51 may be used as the second adhesive 52.

According to this configuration, the lower viscosity of the second adhesive 52 facilitates the entry of the second adhesive 52 into both the first and second connecting portions 90A and 90B when the second adhesive 52 is applied to the section between the coupling portions 839 in droplets. As such, the first and second connecting portions 90A and 90B are easily filled with the second adhesive 52.

At the same time, the use of an adhesive with a higher viscosity as the first adhesive 51 limits protrusion of the first adhesive 51 from the pattern surface 833S of the adhesion patterns 833A and 833B. This reduces the possibility that the first adhesive 51 occupies the first and second connecting portions 90A and 90B.

(12) The adhesion pattern 33 is formed into a rectangular frame shape having a longitudinal direction and a transverse direction in plan view. The cap 70 includes the first to fourth side walls 71 to 74 having the shape of a rectangular frame opposed to the adhesion pattern 33 in the Z-direction. The light transmission surface is formed in the fourth side wall 74, which is a section of the first to fourth side walls 71 to 74 that extends in the longitudinal direction. The connecting portion 90 is provided in the first pattern 35, which is a section of the adhesion pattern 33 that extends in the transverse direction.

According to this configuration, the connecting portion 90 is provided directly below the first side wall 71, which is a section of the first to fourth side walls 71 to 74 extending in the transverse direction. If the connecting portion 90 is provided in the third side wall 73, which is a section of the first to fourth side walls 71 to 74 extending in the longitudinal direction, the connecting portion 90 would be adjacent to the fourth side wall 74 of the cap 70 on the adhesion pattern that is adjacent in the Y-direction in the manufacturing process of the semiconductor light emitting device 10. In this case, in the step of applying the second adhesive 52, the second adhesive 52 may adhere to the fourth side wall 74 of the cap 70 on the adhesion pattern that is adjacent in the Y-direction. In contrast, the present embodiment includes the connecting portion 90 located directly below a section of the first to fourth side walls 71 to 74 extending in the transverse direction, instead of a section extending in the longitudinal direction. This reduces the possibility that the second adhesive 52 adheres to the fourth side wall 74 (light transmission surface).

### Modifications

The embodiment described above may be modified as follows. The above modifications may be combined to an extent that does not cause technical contradiction.

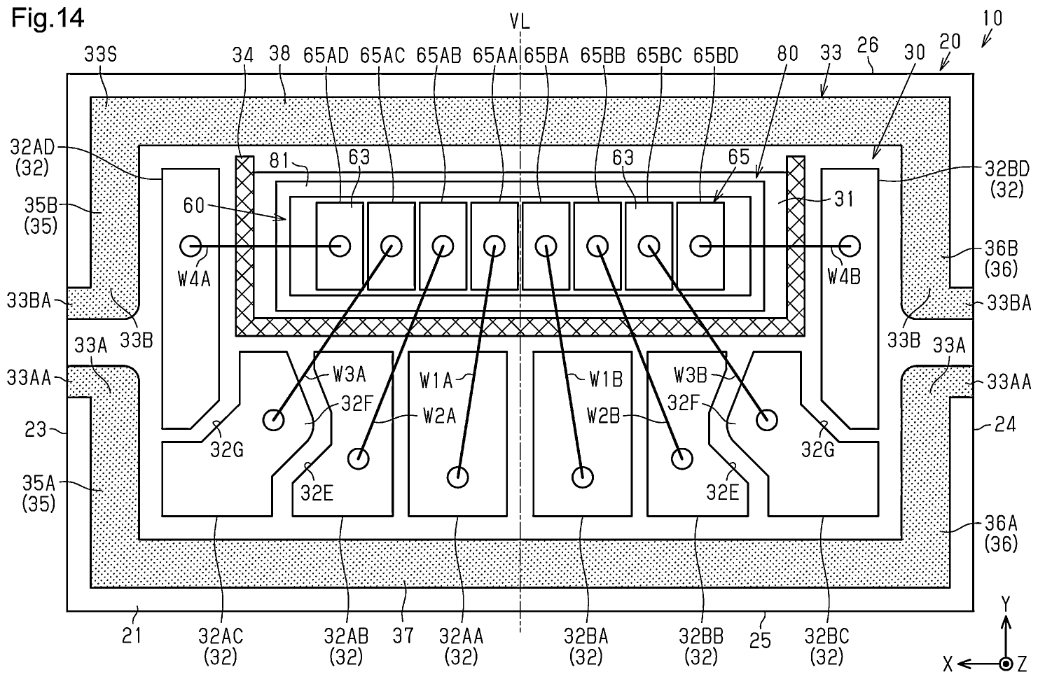

The number and the position of the first and second perimeter end portions 33A and 33B of the adhesion pattern 33 may be modified. For example, the number and the position of the first and second perimeter end portions 33A and 33B of the adhesion pattern 33 may be changed as in the first to third examples shown in FIGS. 14 to 16.

FIG. 14 shows the first example including two pairs of a first perimeter end portion 33A and a second perimeter end portion 33B. More specifically, the first pattern 35 and the second pattern 36 of the adhesion pattern 33 each include first and second perimeter end portions 33A and 33B. The configurations of the first and second perimeter end portions 33A and 33B in the first pattern 35 are the same as the embodiment described above. Since the second pattern 36 includes the first and second perimeter end portions 33A and 33B, the second pattern 36 includes a first split pattern 36A and a second split pattern 36B, which are spaced apart from each other in the Y-direction

The first split pattern 36A is a section of the second pattern 36 that is connected to the third pattern 37. The first split pattern 36A includes the first perimeter end portion 33A. The first split pattern 36A also includes a protrusion pattern 33AA extending from the first perimeter end portion 33A toward the second substrate side surface 24 in plan view. The protrusion pattern 33AA extends from the first perimeter end portion 33A to the second substrate side surface 24.

The second split pattern 36B is a section of the second pattern 36 that is connected to the fourth pattern 38. The second split pattern 36B includes the second perimeter end portion 33B. The second split pattern 36B also includes a protrusion pattern 33BA extending from the second perimeter end portion 33B toward the second substrate side surface 24 in plan view. The protrusion pattern 33BA extends from the second perimeter end portion 33B to the second substrate side surface 24.

The first and second perimeter end portions 33A and 33B of the second pattern 36 may have the same shape and size as the first and second perimeter end portions 33A and 33B of the first pattern 35. Also, the protrusion patterns 33AA and 33BA of the second pattern 36 may have the same shape and size as the protrusion patterns 33AA and 33BA of the first pattern 35.

According to this configuration, when substrates 20 are manufactured by cutting the substrate 820 shown in FIG. 13 along the cutting lines CLX and CLY, for example, protrusion patterns 33AA and 33BA are formed in each of the side corresponding to the first substrate side surface 23 and the side corresponding to the second substrate side surface 24. As such, in the process of manufacturing the semiconductor light emitting device 10, semiconductor light emitting devices 10 of the same appearance are manufactured, instead of two types of semiconductor light emitting devices 10, which are a semiconductor light emitting device 10 including protrusion patterns 33AA and 33BA only on the side corresponding to the first substrate side surface 23, and a semiconductor light emitting device 10 including protrusion patterns 33AA and 33BA only on the side corresponding to the second substrate side surface 24.

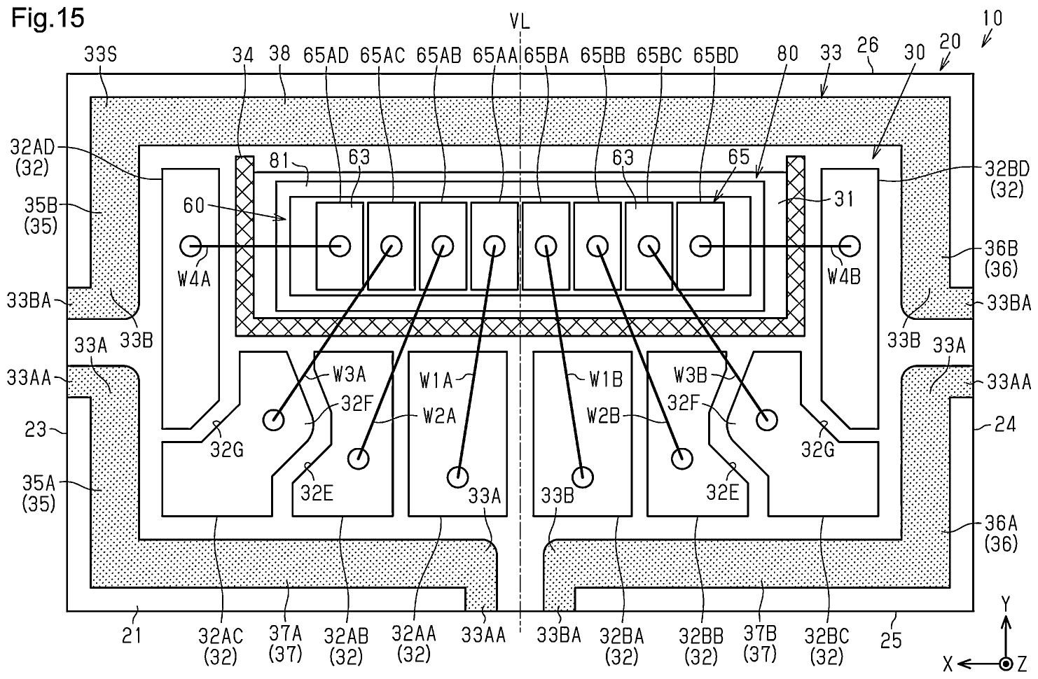

FIG. 15 shows the second example including three pairs of first and second perimeter end portions 33A and 33B. More specifically, the first pattern 35, the second pattern 36, and the third pattern 37 of the adhesion pattern 33 each include first and second perimeter end portions 33A and 33B. The configurations of the first and second perimeter end portions 33A and 33B provided in the first pattern 35 and the second pattern 36 are the same as the first example shown in FIG. 14, and their detailed descriptions are omitted.

Since the third pattern 37 includes first and second perimeter end portions 33A and 33B, the third pattern 37 includes a first split pattern 37A and a second split pattern 37B, which are spaced apart from each other in the X-direction That is, the first and second perimeter end portions 33A and 33B provided in the third pattern 37 split the third pattern 37 in the X-direction.

The first split pattern 37A is a section of the third pattern 37 that is connected to the first pattern 35. The first split pattern 37A includes the first perimeter end portion 33A. The first split pattern 37A also includes a protrusion pattern 33AA extending from the first perimeter end portion 33A toward the third substrate side surface 25 in plan view. The protrusion pattern 33AA extends from the first perimeter end portion 33A to the third substrate side surface 25. The protrusion pattern 33AA may extend in the Y-direction, for example.

The second split pattern 37B is a section of the third pattern 37 that is connected to the second pattern 36. The second split pattern 37B includes the second perimeter end portion 33B. The second split pattern 37B also includes a protrusion pattern 33BA extending from the second perimeter end portion 33B toward the third substrate side surface 25 in plan view. The protrusion pattern 33BA extends from the second perimeter end portion 33B to the third substrate side surface 25. The protrusion pattern 33BA may extend in the Y-direction, for example.

The first and second perimeter end portions 33A and 33B of the third pattern 37 may have the same shape and size as the first and second perimeter end portions 33A and 33B of the first pattern 35. Also, the protrusion patterns 33AA and 33BA of the third pattern 37 may have the same shape and size as the protrusion patterns 33AA and 33BA of the first pattern 35.

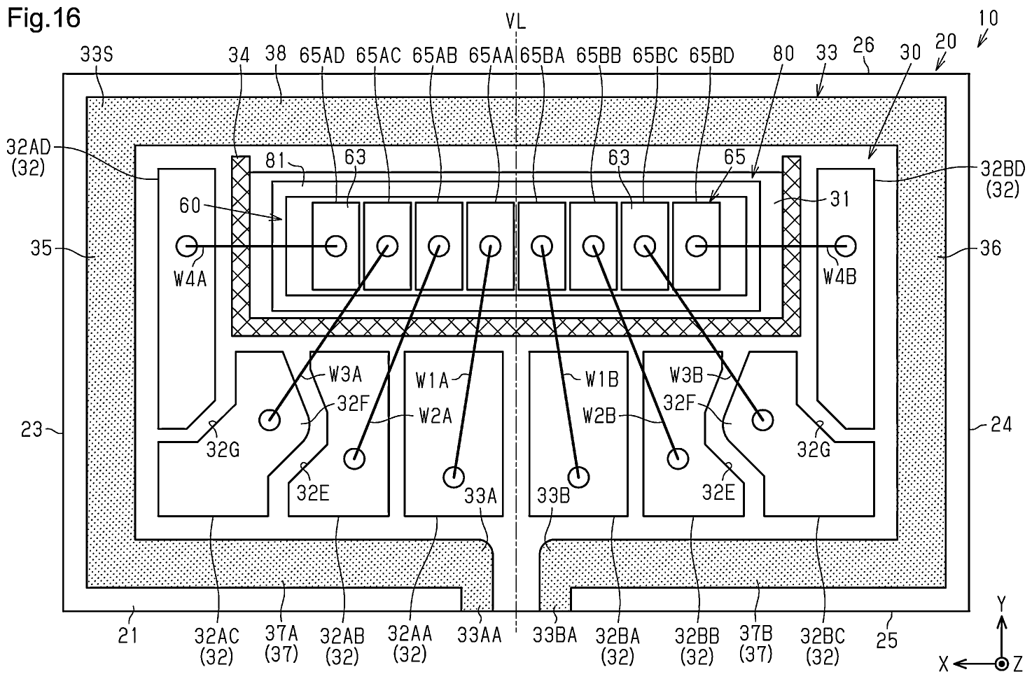

FIG. 16 shows the third example including one pair of first and second perimeter end portions 33A and 33B at a location in the adhesion pattern 33 that differs from that of the above embodiment. More specifically, first and second perimeter end portions 33A and 33B are provided in the third pattern 37. The configurations of the first and second perimeter end portions 33A and 33B provided in the third pattern 37 are the same as the first and second perimeter end portions 33A and 33B provided in the third pattern 37 in the second example of FIG. 15, and their detailed descriptions are omitted.

A pair of first and second perimeter end portions 33A and 33B may be provided in the fourth pattern 38. That is, any configuration may be used as long as the adhesion pattern 33 includes a pair of first and second perimeter end portions 33A and 33b in at least one location.

In the above embodiment and the modifications shown in FIGS. 14 to 16, the positions of the first perimeter end portion 33A and the second perimeter end portion 33B relative to the adhesion pattern 33 may be modified. In one example, the first and second perimeter end portions 33A and 33B in the first pattern 35 do not need to be located at the center of the first pattern 35 in the Y-direction and may be located at positions closer to the third pattern 37 or the fourth pattern 38. That is, the connecting portion 90 is not limited to the center of the first pattern 35 in the Y-direction, and may be located closer to the third pattern 37 or closer to the fourth pattern 38. The first and second perimeter end portions 33A and 33B provided in the second pattern 36 may also be modified in the same manner. Thus, the connecting portion 90 is not limited to the center of the second pattern 36 in the Y-direction, and may be located closer to the third pattern 37 or closer to the fourth pattern 38. The first and second perimeter end portions 33A and 33B in the third pattern 37 do not need to be located at the center of the third pattern 37 in the X-direction and may be located at positions closer to the first pattern 35 or the second pattern 36. That is, the connecting portion 90 is not limited to the center of the third pattern 37 in the X-direction, and may be located closer to the first pattern 35 or closer to the second pattern 36.

The position of the connecting portion 90 in plan view may be modified. In one example, the connecting portion 90 may be provided at the same position as the light transmission surface of the cap 70 (the fourth side wall 74 in the above embodiment). That is, first and second perimeter end portions 33A and 33B may be provided in the fourth pattern 38 of the adhesion pattern 33.

The opening dimension HW of the connecting portion 90 may be modified. In one example, the opening dimension HW of the connecting portion 90 may be greater than the width dimension WA of the adhesion pattern 33.

According to this configuration, the greater opening dimension HW of the connecting portion 90 reduces the possibility that the connecting portion 90 is filled with the first adhesive 51 even if the first adhesive 51 protrudes to the section where the adhesion pattern 33 is interrupted, that is, the section forming the connecting portion 90.

The first adhesive 51 may be formed across the first perimeter end portion 33A and the second perimeter end portion 33B of the adhesion pattern 33. In this case, the connecting portion 90 is formed by the first adhesive 51, the substrate surface 21, the first perimeter end portion 33A, and the second perimeter end portion 33B. In other words, the connecting portion 90 may have any configuration as long as it laterally extends through at least the adhesion pattern 33 in plan view to connect the inside and the outside of the cap 70 to each other. In this case, the thickness of the thick adhesion portion 52A of the second adhesive 52 is less than the distance between the substrate surface 21 and the opening end surface 76 of the cap 70 in the Z-direction.

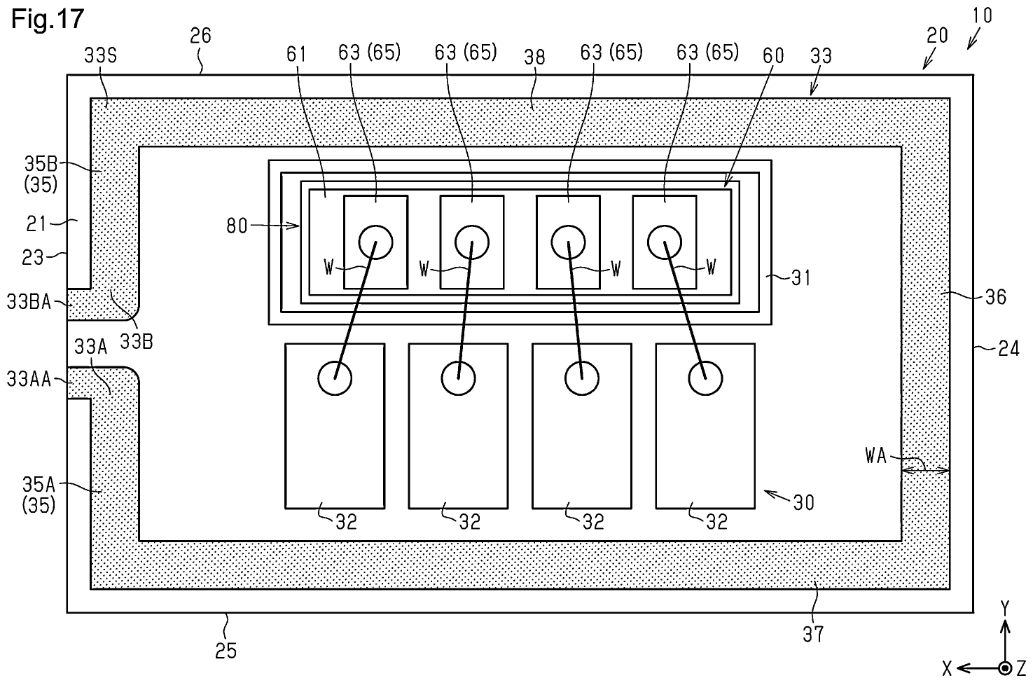

The configuration of the surface electrode 30 may be modified depending on the configuration of the edge-emitting light emitting element 60, for example. In one example, as shown in FIG. 17, the edge-emitting light emitting element 60 includes four light emitting portions 65 (element electrodes 63). The number of wire connection electrodes 32 may be set according to the number of light emitting portions 65 (element electrodes 63), for example. Thus, in the example shown in FIG. 17, the surface electrode 30 includes four wire connection electrodes 32. Each wire connection electrode 32 is rectangular and has a longitudinal direction in the Y-direction and a transverse direction in the X-direction in plan view. The four wire connection electrodes 32 are arranged at the same position in the Y-direction and spaced apart from each other in the X-direction.

The width dimensions WP and WQ of the protrusion patterns 33AA and 33BA may be modified. In one example, the width dimensions WP and WQ of the protrusion patterns 33AA and 33BA may be greater than or equal to the width dimension WA of the adhesion pattern 33. Furthermore, the width dimension WP may be different from the width dimension WQ.

The protrusion patterns 33AA and 33BA may be omitted. In this case, the two coupling portions 839 of the substrate 820 in the process of manufacturing the semiconductor light emitting device 10 may also be omitted.

The type of the second adhesive 52 may be modified. In one example, the second adhesive 52 and the first adhesive 51 may be of the same type. This configuration simplifies the management of the adhesive as compared with a configuration in which the first adhesive 51 and the second adhesive 52 are of different types.

The first and second adhesives 51 and 52 are not limited to thermosetting adhesives, and may be changed. In one example, at least one of the first and second adhesives 51 and 52 may be an ultraviolet curable adhesive, for example. When the first adhesive 51 is an ultraviolet curable adhesive, in the step of bonding the cap 70 to the adhesion pattern 33 by curing the first adhesive 51, ultraviolet light is applied to the first adhesive 51 from the side corresponding to the upper wall 75 of the cap 70. The cap 70 is made of a material that transmits ultraviolet light. The ultraviolet light transmitted through the cap 70 is applied to the first adhesive 51, thereby curing the first adhesive 51. When the second adhesive 52 is an ultraviolet curable adhesive, in the step of solidifying the second adhesive 52, ultraviolet light may be directly applied to the second adhesive 52 in the connecting portion 90, or ultraviolet light may be applied to the second adhesive 52 from the side corresponding to the upper wall 75 of the cap 70.

The shape of the adhesion pattern 33 in plan view may be modified. In one example, the adhesion pattern 33 may have a square frame shape in plan view. In one example, the adhesion pattern 33 in plan view is not limited to a rectangular shape, and may have the shape of an elliptical (stadium-shaped), oval, or circular frame.

The direction in which the connecting portion 90 extends through the adhesion pattern 33 in plan view may be modified. In a state before the connecting portion 90 is filled with the second adhesive 52, the connecting portion 90 may have any configuration as long as it connects the inside and the outside of the cap 70 to each other. As such, in plan view, the connecting portion 90 may extend through the adhesion pattern 33 in a direction intersecting both the X-direction and the Y-direction (for example, a direction inclined at 45 degrees with respect to both the X-direction and the Y-direction in plan view).

Although the edge-emitting light emitting element 60 is used as the semiconductor light emitting element, the configuration of the semiconductor light emitting element is not limited to this. A surface-emitting light emitting element may be used as the semiconductor light emitting element. A vertical cavity surface emitting laser (VCSEL) may be used as an example of a surface-emitting light emitting element. In this case, the cap 70 may be configured such that the upper wall 75 is a light transmission surface. The fourth side wall 74 of the cap 70 may be configured to be translucent as with the first to third side walls 71 to 73. Also, a light emitting diode (LED) may be used as the semiconductor light emitting element.

The above embodiments use the substrate 20 that is made of an insulating material, but there is no limitation to this. The substrate 20 may be made of a metal material such as Cu or Al. In this case, an insulating layer is formed on the front and back surfaces of a flat frame (for example, a metal core) made of Cu, Al, or the like. Multiple surface electrodes 30 and adhesion patterns 33 are formed on the insulating layer (substrate surface 21) formed on the surface of the frame. Multiple back electrodes 40 are formed on the insulating layer (substrate back surface 22) formed on the back surface of the frame. Multiple through-substrate interconnections extend through the frame in the thickness direction (Z-direction) to electrically connect the back electrodes 40 to the corresponding surface electrodes 30. In this case, an insulating layer is formed on the inner surface defining each through-hole formed in the frame. Each through-substrate interconnection is formed to fill the space formed by the insulating layer.

In the above embodiment, the configurations of the substrate 20, the surface electrodes 30, the back electrodes 40, and the through-substrate interconnections may be modified. In one example, instead of the surface electrodes 30, the back electrodes 40, and the through-substrate interconnections, the semiconductor light emitting device 10 may include frames each including a surface electrode 30, a back electrode 40, and a through-substrate interconnection, which are integrally formed, and a substrate, which supports the frames and is made of an insulating material. In this case, the number of the frames corresponds to the number of surface electrodes 30 (back electrodes 40). The substrate is made of an insulating material, which may be epoxy resin, for example. The frames are provided to extend through the substrate in the Z-direction. As such, the sections of the frames exposed from the substrate surface form the surface electrodes 30, and the sections of the frames exposed from the substrate back surface form the back electrodes 40. The adhesion pattern 33 may be formed as a frame extending through the substrate in the Z-direction, or may be formed as a metal layer on the substrate surface. The frame forming the adhesion pattern 33 may be formed by the same frame as the frame in which the surface electrode 30, the back electrode 40, and the through-substrate interconnection are integrated, or may be formed as a different frame.

One or more of the various examples described in this specification may be combined within a range where there is no technical inconsistency.

In this specification, “at least one of A and B” should be understood to mean “only A, or only B, or both A and B.”

In the present disclosure, the term “on” includes the meaning of “above” in addition to the meaning of “on” unless otherwise clearly indicated in the context. Therefore, for example, the phrase “first component disposed on second component” is intended to mean that the first component may be disposed on the second component in contact with the second component in one embodiment and that the first component may be disposed above the second component without contacting the second component in another embodiment. In other words, the term “on” does not exclude a structure in which another component is formed between the first component and the second component.

The Z-direction referred to in the present disclosure does not necessarily have to be the vertical direction and does not necessarily have to exactly coincide with the vertical direction. In the structures according to the present disclosure, “upward” and “downward” in the z-direction as referred to in the present description are not limited to “upward” and “downward” in the vertical direction. For example, the X-direction may conform to the vertical direction. The Y-direction may conform to the vertical direction.

### CLAUSES

Technical concepts that can be understood from each of the above embodiments and modified examples will now be described. The reference characters used to denote elements of the embodiments are shown in parenthesis for the corresponding elements of the clauses described below. The reference signs used as examples to facilitate understanding, and the elements in each clause are not limited to those elements given with the reference signs.

### Clause 1

A semiconductor light emitting device (10) including:
a substrate (20);
a semiconductor light emitting element (60) placed on the substrate (20);
a cap (70) accommodating the semiconductor light emitting element (60);
an adhesion pattern (33) disposed on the substrate (20) so as to surround the semiconductor light emitting element (60) as viewed from a thickness direction (Z-direction) of the substrate (20);
a first adhesive (51) bonding the cap (70) to a pattern surface (33S) of the adhesion pattern (33);
a connecting portion (90) extending laterally through at least the adhesion pattern (33) as viewed from the thickness direction (Z-direction) to connect an inside of the cap (70) and an outside of the cap (70) to each other; and a second adhesive (52) with which the connecting portion (90) is filled.

### Clause 2

The semiconductor light emitting device according to clause 1, wherein
the adhesion pattern (33) has a frame shape having a predetermined width and extending in a length direction perpendicular to the width, and
the connecting portion (90) extends through the adhesion pattern (33) in a direction of the width so as to split the adhesion pattern (33) in the length direction of the adhesion pattern (33).

### Clause 3

The semiconductor light emitting device according to clause 1 or 2, wherein the connecting portion (90) has an opening dimension (HW) that is less than or equal to a width dimension (WA) of the adhesion pattern (33).

### Clause 4

The semiconductor light emitting device according to clause 1 or 2, wherein the connecting portion (90) has an opening dimension (HW) that is greater than a width dimension (WA) of the adhesion pattern (33).

### Clause 5

The semiconductor light emitting device according to clause 3 or 4, wherein
the connecting portion (90) is a region between the first perimeter end portion (33A) and the second perimeter end portion (33B), and
the opening dimension (HW) is a distance between the first perimeter end portion (33A) and the second perimeter end portion (33B).

### Clause 6

The semiconductor light emitting device according to any one of clauses 1 to 5, wherein
the semiconductor light emitting element (60) is an edge-emitting light emitting element (60) configured to emit light in a lateral direction that intersects the thickness direction (Z-direction),
the adhesion pattern (33) has a rectangular frame shape as viewed from the thickness direction (Z-direction),
the cap (70) includes a light transmission surface (74) located at a position corresponding to one side (38) of the adhesion pattern (33) as viewed from the thickness direction (Z-direction), and
the connecting portion (90) is disposed in a side (35) of the adhesion pattern (33), the side differing from the side (38) corresponding to the light transmission surface (74).

### Clause 7

The semiconductor light emitting device according to clause 6, wherein
the adhesion pattern (33) has a rectangular frame shape having a longitudinal direction and a transverse direction as viewed from the thickness direction (Z-direction),
the cap (70) includes a side wall (71-74) that has a rectangular frame shape and is opposed to the adhesion pattern (33) in the thickness direction (Z-direction),
the light transmission surface is disposed in a section (74) of the side wall (71-74), the section extending in the longitudinal direction, and
the connecting portion (90) is disposed in a section (35) of the adhesion pattern (33), the section extending in the transverse direction.

### Clause 8

The semiconductor light emitting device according to any one of clauses 1 to 7, wherein
the adhesion pattern (33) includes a first perimeter end portion (33A) and a second perimeter end portion (33B) defining the connecting portion (90), and
the first perimeter end portion (33A) and the second perimeter end portion (33B) each include a protrusion pattern (33AA, 33BA) that protrudes from the cap (70) as viewed from the thickness direction (Z-direction).

### Clause 9

The semiconductor light emitting device according to clause 8, wherein the protrusion pattern (33AA, 33BA) has a width dimension (WP, WQ) that is less than a width dimension (WA) of the adhesion pattern (33).

### Clause 10

The semiconductor light emitting device according to any one of clauses 1 to 9, wherein the substrate (20) includes a substrate surface (21) including the adhesion pattern (33), and
the second adhesive (52) is in contact with the substrate surface (21).

### Clause 11

The semiconductor light emitting device according to clause 10, wherein the second adhesive (52) includes a thick adhesion portion (52A) having a greater thickness than the first adhesive (51).

### Clause 12

The semiconductor light emitting device according to clause 11, wherein the thickness of the thick adhesion portion (52A) is equal to a sum of a thickness of the first adhesive (51) and a thickness of the adhesion pattern (33).

### Clause 13

The semiconductor light emitting device according to clause 11 or 12, wherein
the cap (70) includes a frame-shaped side wall (71-74) including an opening end surface (76),
the thick adhesion portion (52A) is in contact with the opening end surface (76) at a position opposed to the opening end surface (76), and
the second adhesive (52) includes a protrusion portion (52B) being continuous with the thick adhesion portion (52A) and protruding from the side wall (71-74) as viewed from the thickness direction (Z-direction).

### Clause 14

The semiconductor light emitting device according to any one of clauses 1 to 13, wherein the second adhesive (52) differs from the first adhesive (51) in type.

### Clause 15

The semiconductor light emitting device according to clause 14, wherein the second adhesive (52) has a lower viscosity than the first adhesive (51).

### Clause 16

The semiconductor light emitting device according to any one of clauses 1 to 13, wherein the first adhesive (51) and the second adhesive (52) are adhesives of the same type.

### Clause 17

A method for manufacturing a semiconductor light emitting device (10), the method comprising:
placing a semiconductor light emitting element (60) on a substrate (820) having a substrate surface (821);
applying a first adhesive (51) to an adhesion pattern (833) on the substrate (820), the adhesion pattern (833) surrounding the semiconductor light emitting element (60) as viewed from a thickness direction (Z-direction) of the substrate (820);
accommodating the semiconductor light emitting element (60) by placing a cap (70) on the first adhesive (51); and
bonding the cap (70) to the adhesion pattern (833) by curing the first adhesive (51), wherein
in the bonding the cap (70) to the adhesion pattern (833), a connecting portion (90) extending laterally through at least the adhesion pattern (833) as viewed from the thickness direction (Z-direction) is defined to connect an inside of the cap (70) and an outside of the cap (70) to each other, and
the method further includes filling the connecting portion (90) with a second adhesive (52) after the bonding the cap (70) to the adhesion pattern (53) by curing the first adhesive (51).

### Clause 18

The method for manufacturing a semiconductor light emitting device according to clause 17, wherein
the adhesion pattern (833) has a frame shape having a predetermined width and extending in a length direction perpendicular to the width as viewed from the thickness direction (Z-direction),
the connecting portion (90) extends through the adhesion pattern (833) in a direction of the width so as to split the adhesion pattern (833) in the length direction of the adhesion pattern (833), and
the applying the first adhesive (51) to the adhesion pattern (833) includes applying the first adhesive (51) to a pattern surface (833S) of the adhesion pattern (833) without applying the first adhesive (51) to the connecting portion (90).

### Clause 19

The method for manufacturing a semiconductor light emitting device according to clause 17 or 18, wherein
the adhesion pattern (833) includes:
   a first adhesion pattern (833A) and a second adhesion pattern (833B) arranged in a first direction (X-direction) as viewed from the thickness direction (Z-direction); and
   two coupling portions (839) that are disposed between the first and second adhesion patterns (833A, 833B) in the first direction (X-direction), are spaced apart from each other in a second direction (Y-direction) perpendicular to the first direction (X-direction), and connect the first adhesion pattern (833A) to the second adhesion pattern (833B) in the first direction (X-direction),
the connecting portion (90) includes:
   a first connecting portion (90A) that connects an inside of a first cap (70) bonded to the first adhesion pattern (833A) and an outside of the first cap (70) to each other; and
   a second connecting portion (90B) that connects an inside of a second cap (70) bonded to the second adhesion pattern (833B) and an outside of the second cap (70) to each other,
the first cap (70) and the second cap (70) correspond to the cap (70),
the applying the first adhesive (51) to the adhesion pattern (833A, 833B) includes applying the first adhesive (51) to pattern surfaces (833S) of the first adhesion pattern (833A) and the second adhesion pattern (833B),
the accommodating the semiconductor light emitting element (60) includes placing the first cap (70) on the first adhesive (51) on the first adhesion pattern (833A) and placing the second cap (70) on the first adhesive (51) on the second adhesion pattern (833B),
the bonding the cap (70) to the adhesion pattern (833A, 833B) includes forming the first connecting portion (90A) by the first adhesion pattern (833A) and the first cap (70) and forming the second connecting portion (90B) by the second adhesion pattern (833B) and the second cap (70), and
the filling the connecting portion (90) with the second adhesive (52) includes applying the second adhesive (52) in droplets to the substrate surface (821) between the two coupling portions (839) to fill both the first and second connecting portions (90A, 90B) with the second adhesive (52).

### Clause 20

The method for manufacturing a semiconductor light emitting device according to clause 19, further including cutting the second adhesive (52), the coupling portions (839), and the substrate (820) in the second direction (Y-direction).

### Clause 21

The method for manufacturing a semiconductor light emitting device according to any one of clauses 17 to 20, wherein the bonding the cap (70) to the adhesion pattern (833A, 833B) by curing the first adhesive (51) includes thermally curing the first adhesive (51).

### Clause 22

The method for manufacturing a semiconductor light emitting device according to any one of clauses 17 to 20, wherein the bonding the cap (70) to the adhesion pattern (833A, 833B) by curing the first adhesive (51) includes performing ultraviolet curing of the first adhesive (51).

### Clause 23

The method for manufacturing a semiconductor light emitting device according to any one of clauses 17 to 22, further including performing thermal curing of the second adhesive (52).

### Clause 24

The method for manufacturing a semiconductor light emitting device according to any one of clauses 17 to 22, further including performing ultraviolet curing of the second adhesive (52).

The above description is merely exemplary. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The present disclosure is intended to include any substitute, modification, changes included in the scope of the disclosure including the claims.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor light emitting device, comprising:
a substrate;
a semiconductor light emitting element placed on the substrate;
a cap accommodating the semiconductor light emitting element;
an adhesion pattern disposed on the substrate so as to surround the semiconductor light emitting element as viewed from a thickness direction of the substrate;
a first adhesive bonding the cap to a pattern surface of the adhesion pattern;
a connecting portion extending laterally through at least the adhesion pattern as viewed from the thickness direction to connect an inside of the cap and an outside of the cap to each other; and
a second adhesive with which the connecting portion is filled.

2. The semiconductor light emitting device according to claim 1, wherein
the adhesion pattern has a frame shape having a predetermined width and extending in a length direction perpendicular to the width, and
the connecting portion extends through the adhesion pattern in a direction of the width so as to split the adhesion pattern in the length direction of the adhesion pattern.

3. The semiconductor light emitting device according to claim 1, wherein the connecting portion has an opening dimension that is less than or equal to a width dimension of the adhesion pattern.

4. The semiconductor light emitting device according to claim 1, wherein the connecting portion has an opening dimension that is greater than a width dimension of the adhesion pattern.

5. The semiconductor light emitting device according to claim 3, wherein
the adhesion pattern includes a first perimeter end portion and a second perimeter end portion that are opposed to each other,
the connecting portion is a region between the first perimeter end portion and the second perimeter end portion, and
the opening dimension is a distance between the first perimeter end portion and the second perimeter end portion.

6. The semiconductor light emitting device according to claim 4, wherein
the adhesion pattern includes a first perimeter end portion and a second perimeter end portion that are opposed to each other,
the connecting portion is a region between the first perimeter end portion and the second perimeter end portion, and
the opening dimension is a distance between the first perimeter end portion and the second perimeter end portion.

7. The semiconductor light emitting device according to claim 1, wherein
the semiconductor light emitting element is an edge-emitting light emitting element configured to emit light in a lateral direction that intersects the thickness direction,
the adhesion pattern has a rectangular frame shape as viewed from the thickness direction,
the cap includes a light transmission surface configured to transmit light emitted from the edge-emitting light emitting element at a position corresponding to one side of the adhesion pattern as viewed from the thickness direction, and
the connecting portion is disposed in a side of the adhesion pattern, the side differing from the side corresponding to the light transmission surface.

8. The semiconductor light emitting device according to claim 7, wherein
the adhesion pattern has a rectangular frame shape having a longitudinal direction and a transverse direction as viewed from the thickness direction,
the cap includes a side wall that has a rectangular frame shape and is opposed to the adhesion pattern in the thickness direction,
the light transmission surface is disposed in a section of the side wall, the section extending in the longitudinal direction, and
the connecting portion is disposed in a section of the adhesion pattern, the section extending in the transverse direction.

9. The semiconductor light emitting device according to claim 1, wherein
the adhesion pattern includes a first perimeter end portion and a second perimeter end portion defining the connecting portion, and
the first perimeter end portion and the second perimeter end portion each include a protrusion pattern that protrudes from the cap as viewed from the thickness direction.

10. The semiconductor light emitting device according to claim 9, wherein the protrusion pattern has a width dimension that is less than a width dimension of the adhesion pattern.

11. The semiconductor light emitting device according to claim 1, wherein the substrate includes a substrate surface including the adhesion pattern, and
the second adhesive is in contact with the substrate surface.

12. The semiconductor light emitting device according to claim 11, wherein the second adhesive includes a thick adhesion portion having a greater thickness than the first adhesive.

13. The semiconductor light emitting device according to claim 12, wherein the thickness of the thick adhesion portion is equal to a sum of a thickness of the first adhesive and a thickness of the adhesion pattern.

14. The semiconductor light emitting device according to claim 12, wherein
the cap includes a frame-shaped side wall including an opening end surface,
the thick adhesion portion is in contact with the opening end surface at a position opposed to the opening end surface, and
the second adhesive includes a protrusion portion being continuous with the thick adhesion portion and protruding from the side wall as viewed from the thickness direction.

15. The semiconductor light emitting device according to claim 1, wherein the second adhesive differs from the first adhesive in type.

16. The semiconductor light emitting device according to claim 15, wherein the second adhesive has a lower viscosity than the first adhesive.

17. The semiconductor light emitting device according to claim 1, wherein the first adhesive and the second adhesive are adhesives of the same type.

18. A method for manufacturing a semiconductor light emitting device, the method comprising:
placing a semiconductor light emitting element on a substrate having a substrate surface;
applying a first adhesive to an adhesion pattern on the substrate, the adhesion pattern surrounding the semiconductor light emitting element as viewed from a thickness direction of the substrate;
accommodating the semiconductor light emitting element by placing a cap on the first adhesive; and
bonding the cap to the adhesion pattern by curing the first adhesive, wherein
in the bonding the cap to the adhesion pattern, a connecting portion extending laterally through at least the adhesion pattern as viewed from the thickness direction is defined to connect an inside of the cap and an outside of the cap to each other, and
the method further comprises filling the connecting portion with a second adhesive after the bonding the cap to the adhesion pattern by curing the first adhesive.

19. The method for manufacturing a semiconductor light emitting device according to claim 18, wherein
the adhesion pattern has a frame shape having a predetermined width and extending in a length direction perpendicular to the width as viewed from the thickness direction,
the connecting portion extends through the adhesion pattern in a direction of the width so as to split the adhesion pattern in the length direction of the adhesion pattern, and
the applying the first adhesive to the adhesion pattern includes applying the first adhesive to a pattern surface of the adhesion pattern without applying the first adhesive to the connecting portion.

20. The method for manufacturing a semiconductor light emitting device according to claim 18, wherein
the adhesion pattern includes:
a first adhesion pattern and a second adhesion pattern arranged in a first direction as viewed from the thickness direction; and
two coupling portions that are disposed between the first and second adhesion patterns in the first direction, are spaced apart from each other in a second direction perpendicular to the first direction, and connect the first adhesion pattern to the second adhesion pattern in the first direction,
the connecting portion includes:
a first connecting portion that connects an inside of a first cap bonded to the first adhesion pattern and an outside of the first cap to each other; and
a second connecting portion that connects an inside of a second cap bonded to the second adhesion pattern and an outside of the second cap to each other,
the first cap and the second cap correspond to the cap,
the applying the first adhesive to the adhesion pattern includes applying the first adhesive to pattern surfaces of the first adhesion pattern and the second adhesion pattern,
the accommodating the semiconductor light emitting element includes placing the first cap on the first adhesive on the first adhesion pattern and placing the second cap on the first adhesive on the second adhesion pattern,
the bonding the cap to the adhesion pattern includes defining the first connecting portion by the first adhesion pattern and the first cap and defining the second connecting portion by the second adhesion pattern and the second cap, and
the filling the connecting portion with the second adhesive includes applying the second adhesive in droplets to the substrate surface between the two coupling portions to fill both the first and second connecting portions with the second adhesive.

21. The method for manufacturing a semiconductor light emitting device according to claim 20, further comprising cutting the second adhesive, the coupling portions, and the substrate in the second direction.
